(19) United States
(12) Patent Application Publication
(10) Pub. No.: US 2023/0104043 A1
(43) Pub. Date: Apr. 6, 2023

(54) CEMENT KILN MODELING FOR IMPROVED OPERATION

(71) Applicant: University of Florida Research Foundation, Gainesville, FL (US)

(72) Inventors: Christopher Charles Ferraro, Gainesville, FL (US); Benjamin E. Watts, Gainesville, FL (US); Chengcheng Tao, Gainesville, FL (US); Forrest James Masters, Gainesville, FL (US)

(21) Appl. No.: 17/773,179

(22) PCT Filed: Oct. 29, 2020
(86) PCT No.: PCT/US2020/058025

§ 371 Date: Apr. 29, 2022

Related U.S. Application Data
(60) Provisional application No. 62/927,533, filed on Oct. 29, 2019.

(51) Int. Cl. G06F 30/25; G06F 30/23; F27B 7/42

(52) U.S. Cl. CPC G06F 30/25; G06F 30/23; F27B 7/42

(57) ABSTRACT

A system and method for controlling operations of a cement kiln plant. The system comprises first and second processing logic. The first processing logic is configured to perform an integrated modeling computer program comprising a Virtual Cement and Concrete Testing Laboratory (VCCTL) modeling computer program and a virtual cement plant (VCP) modeling computer program. The first processing logic receives output of the VCP modeling computer program and imports the output into the VCCTL modeling computer program. The second processing logic is configured to perform one or more multi-objective metaheuristic optimization computer programs on output of the integrated modeling computer program to adjust control parameters that are used to control the operations of the cement kiln plant. The integrated model can provide a quantitative optimization tool for different energy efficiency measures addressed from cement plants and reduce energy, material consumption and greenhouse gas emissions without losing the performance of material.

### CROSS-REFERENCE TO RELATED APPLICATIONS

The present application is a nonprovisional PCT international application that claims the benefit of and priority to the filing date of U.S. provisional application Ser. No. 62/927,533, filed on Oct. 29, 2019 and entitled “CEMENT KILN MODELING FOR IMPROVED OPERATION,” which is hereby incorporated by reference herein in its entirety.

### TECHNICAL FIELD

The present disclosure relates to a system and method for modeling cement and a cement kiln.

### BACKGROUND

Portland cement concrete is widely used in the global construction industry because of its flexibility in civil engineering applications and the widespread availability of its constituent materials. There is, however, a growing need to reduce the energy costs and environmental impact associated with cement production. From an operational perspective, the goal is to increase energy efficiency without sacrificing productivity.

Plants have incorporated efficiency measures during raw meal preparation, clinker production, and finish grinding, among other areas. For example, process knowledge based systems (KBS) have been applied to the energy management and process control during clinker production. Also, switching from coal to natural gas as the fuel for the cement kiln has been shown to provide higher flame temperature, higher levels of clinker production (5-10%), lower fuel consumption, lower build-ups and dust losses. Due to the complexity of the reactions of cement hydration and scale of the cement plant, full scale experimental testing for cement properties and energy cost within the production are costly and impractical. Therefore, there is an increasing need for the development of computational modeling for cement and the cement plant.

### SUMMARY

A system, method and computer program are disclosed herein for modeling cement and a cement kiln plant. The system comprises at least a first processor and memory in communication with the processor(s). The processor(s) is configured to perform an integrated modeling computer program comprising a Virtual Cement and Concrete Testing Laboratory (VCCTL) modeling computer program and a virtual cement plant (VCP) modeling computer program. The VCP modeling computer program receives VCP input and produces a VCP output. The VCCTL modeling computer program receives the VCP output and produces a virtual cement performance based at least in part on the VCP output received by the VCCTL modeling computer program from the VCP modeling computer program.

In accordance with a representative embodiment, the processor(s) is also configured to perform one or more multi-objective metaheuristic optimization computer programs.

In accordance with a representative embodiment, the one or more multi-objective metaheuristic optimization computer programs terminate when preselected convergence criteria are met.

In accordance with a representative embodiment, the one or more multi-objective metaheuristic optimization computer programs generate a plurality of Pareto fronts from the output of the integrated modeling computer program.

In accordance with a representative embodiment, a respective Pareto front is generated for each of a plurality of objectives of a multi-objective optimization problem associated with the VCCTL modeling computer program.

In accordance with a representative embodiment, the one or more multi-objective metaheuristic optimization computer programs perform at least one of a particle swarm optimization (PSO) algorithm and a genetic algorithm (GA).

In accordance with a representative embodiment, the virtual cement performance provides information regarding control parameters for the cement kiln plant that can be adjusted to reduce material costs and consumption.

In accordance with a representative embodiment, the virtual cement performance provides information regarding control parameters for the cement kiln plant that can be adjusted to decrease carbon dioxide emissions that are emitted by the cement kiln plant.

The method for modeling cement and a cement kiln plant comprises:
in at least a first processor:
   performing an integrated modeling computer program comprising a Virtual Cement and Concrete Testing Laboratory (VCCTL) modeling computer program and a virtual cement plant (VCP) modeling computer program, the VCP modeling computer program receiving VCP input and producing a VCP output; and
   receiving the VCP output in the VCCTL modeling computer program and performing the VCCTL modeling computer program to produce a virtual cement performance based at least in part on the VCP output received by the VCCTL modeling computer program from the VCP modeling computer program.

In accordance with a representative embodiment of the method, the method further comprises:
in at least the first processor:
   performing one or more multi-objective metaheuristic
optimization computer programs.

In accordance with a representative embodiment of the method, the one or more multi-objective metaheuristic optimization computer programs terminate when preselected convergence criteria are met.

In accordance with a representative embodiment of the method, the one or more multi-objective metaheuristic optimization computer programs generate a plurality of Pareto fronts from the output of the integrated modeling computer program.

In accordance with a representative embodiment of the method, a respective Pareto front is generated for each of a plurality of objectives of a multi-objective optimization problem associated with the VCCTL modeling computer program.

In accordance with a representative embodiment of the method, the one or more multi-objective metaheuristic optimization computer programs comprise at least one of a PSO algorithm and a GA.

In accordance with a representative embodiment of the method, the virtual cement performance provides information regarding control parameters for the cement kiln plant that can be adjusted to decrease carbon dioxide emissions that are emitted by the cement kiln plant.

In accordance with a representative embodiment of the method, the virtual cement performance provides information regarding control parameters for the cement kiln plant that can be adjusted to reduce material costs and consumption.

In accordance with a representative embodiment, an integrated modeling computer program comprises a VCCTL modeling computer program and a VCP modeling computer program. The integrated modeling computer program comprises computer instructions for execution by at least a first processor. The integrated modeling computer program comprises:
VCP modeling computer instructions that receive VCP input and produce VCP output; and
VCCTL modeling computer instructions that receive the VCP output and produce a virtual cement performance based at least in part on the VCP output received by the VCCTL modeling computer program from the VCP modeling computer program.

In accordance with a representative embodiment, the integrated modeling computer program further comprises multi-objective metaheuristic optimization computer instructions.

In accordance with a representative embodiment, the multi-objective metaheuristic optimization computer instructions comprise instructions for generating a plurality of Pareto fronts.

In accordance with a representative embodiment, the multi-objective metaheuristic optimization computer instructions comprise instructions for performing at least one of a PSO algorithm and a GA.

These and other features and advantages will become apparent from the following description, drawings and claims.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows a schematic diagram of a rotary cement kiln.

FIG. 2 shows a cross-section of a cement kiln depicting three types of heat transfer, namely, radiation, convection and conduction.

FIG. 3 is a diagram that shows the heat transfer between an internal wall, freeboard gas and a solid bed inside of a cement rotary kiln.

FIG. 4 shows a three-dimensional (3-D) image of the initial microstructure from a VCCTL.

FIG. 5 illustrates a flow diagram of the VCCTL model algorithm in accordance with a representative embodiment.

FIG. 6 is a plot of E vs. time of set and type of cement for a plurality of cements; w/c is also shown.

FIG. 7 depicts the number of computer simulations as a function of the variable count and shows that adding one new variable (e.g., concrete fineness) can increase the run time by a factor of ten.

FIG. 8 is a plot of E as a function of iteration with PSO and shows the values of the objective function for 100 iterations.

FIG. 9 shows the distribution of each cement phase at the optimal solution calculated by the PSO method.

FIG. 10 is a plot of E as a function of time of a set of Pareto fronts of four different bi-objective optimization scenarios without constraints compared with the data envelope.

FIG. 11 shows plots of E vs. time of set using a Genetic Algorithm (GA) and a Particle Swarm optimization (PSO) algorithm for a bi-objective optimization problem, demonstrating that the results from both methods are appropriate to solve the bi-objective optimization problem of the VCCTL.

FIGS. 12A-12D show the Pareto fronts for different water to cement ratios when minimizing time of set, minimizing kiln temperature proxy, and maximizing 7-day elastic modulus.

FIG. 13A-13C show 3-D surface meshes of Pareto fronts from a non-dominated solution for the Max-Max-Max case, for the Min-Min-Min case and for the combined cases, respectively.

FIG. 14 is a plot showing the relation between population size, convergence generation and number of PSO simulations and demonstrates that, with increasing population size, the number of generations needed for convergence decreases and the number of optimal solutions increases.

FIG. 15A shows the process of finding the convex hull for Min (Time of set)−Min (C3S/C2S)−Min (E) case; FIG. 15B shows the process of finding the convex hull for Max (Time of set)−Max (C3S/C2S)−Max (E) case; FIGS. 15C and D show the combined convex hull.

FIG. 16 demonstrates a scoring procedure for two example cements.

FIGS. 17A-17F show an example case for the application of objective, performance based scoring to cement paste design with respect to user needs for time of set, C₃S/C₂S, and w/c; FIGS. 17A, 17C and 17E show the spectrum of combined scores with 75%, 50%, and 25% weight, respectively, for C₃S/C₂S. FIGS. 17B, 17D and 17F show the portion of the dataset with a score exceeding 0.7 for each set of weights.

FIG. 18 shows plots of a temperature profiles of the cement kiln vs. kiln length.

FIG. 19 shows species mass fraction along the axial length of the cement kiln without adjusting bed height, which generates 20% more C₃S compared with a previous result.

FIG. 20 shows the species mass fractions along the cement kiln after adjusting the bed height from 0.75 m to 0.58 m.

FIG. 21 shows the temperature profiles of solid bed, shell, internal wall and freeboard gas along the kiln.

FIGS. 22 and 23 show distributions of raw meal of 1956 inputs generated utilizing fixed intervals and uniformly distributed random numbers based on the ranges from each input, respectively.

FIGS. 24 and 25 show distributions of inputs generated by uniformly distributed random numbers from the available section and distribution of raw meal.

FIG. 26 shows a plot of normalized kiln length vs. temperature as an example of gas temperature as an input profile for the VCP.

FIGS. 27A-27D show a table of comparison of VCP cases with different material input range.

FIG. 28 is a flow diagram of the coupled VCP-VCCTL model algorithm in accordance with a representative embodiment.

FIGS. 29A-29J show a table of coupled VCP-VCCTL results with 53,700 inputs.

FIG. 30 is a plot of cost of raw meal vs. modulus showing that modulus increases with an increase in the cost of raw meal for different temperatures.

FIG. 31 is a plot of cost of fuel vs. modulus.

FIG. 32 is a plot of combined cost of fuel and raw meal vs. modulus showing that modulus increases with total cost.

FIG. 33 is a plot of Pareto fronts of four different bi-objective scenarios showing the trade-off between modulus and material cost.

FIG. 34 is a plot of kiln length vs. mass fraction calculated by the VCP of the integrated model.

FIG. 35 is a plot of four Pareto fronts for different optimization scenarios on E vs. CO₂ emission from limestone decomposition.

FIG. 36 is a block diagram of the system in accordance with a representative embodiment for executing the coupled VCP/VCCTL model and the multi-objective metaheuristic algorithm.

### DETAILED DESCRIPTION

The present disclosure discloses metaheuristic systems, methods and algorithms that are applied to virtual cement and cement plant modeling. The Virtual Cement and Concrete Testing Laboratory (VCCTL), which is available for commercial use from the National Institute of Standards and Technology (NIST), incorporates microstructural modeling of Portland cement hydration and supports the prediction of different properties of hydrated products. For computational modeling both in cement and the cement plant, the number of control parameters are sufficiently large that it is impossible to analyze all combinatorial cases. Thus, the problem of identifying optimal mixtures is not possible without introducing techniques that utilize a smaller sample space. Some statistical methods have been used to conduct the optimization for high performance concrete and cement; however, these methods have some difficulties in solving large discrete problems with multi-objective optimization problems due to computational limitations. Cement plant models have also been investigated to simulate heat and chemistry in cement production. These models predicted the behavior cement plant with respect to heat transfer and clinker formation inside the cement rotary kiln considering given kiln conditions and raw material inputs.

In the following detailed description, for purposes of explanation and not limitation, exemplary, or representative, embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only and is not intended to be limiting. The defined terms are in addition to the technical and scientific meanings of the defined terms as commonly understood and accepted in the technical field of the present teachings.

As used in the specification and appended claims, the terms “a,” “an,” and “the” include both singular and plural referents, unless the context clearly dictates otherwise. Thus, for example, “a device” includes one device and plural devices.

Relative terms may be used to describe the various elements' relationships to one another, as illustrated in the accompanying drawings. These relative terms are intended to encompass different orientations of the device and/or elements in addition to the orientation depicted in the drawings.

It will be understood that when an element is referred to as being “connected to” or “coupled to” or “electrically coupled to” another element, it can be directly connected or coupled, or intervening elements may be present.

The term “memory” or “memory device”, as those terms are used herein, are intended to denote a non-transitory computer-readable storage medium that is capable of storing computer instructions, or computer code, for execution by one or more processors. References herein to “memory” or “memory device” should be interpreted as one or more memories or memory devices. The memory may, for example, be multiple memories within the same computer system. The memory may also be multiple memories distributed amongst multiple computer systems or computing devices.

A “processor” or “processing logic,” as those terms are used herein encompass an electronic component that is able to execute a computer program or executable computer instructions. References herein to a computer comprising “a processor” or “processing logic” should be interpreted as one or more processors, processing cores or instances of processing logic. The processor may for instance be a multi-core processor. A processor may also refer to a collection of processors within a single computer system or distributed amongst multiple computer systems. The term “computer” should also be interpreted as possibly referring to a collection or network of computers or computing devices, each comprising a processor or processors. Instructions of a computer program can be performed by multiple processors that may be within the same computer or that may be distributed across multiple computers.

Exemplary, or representative, embodiments will now be described with reference to the figures, in which like reference numerals represent like components, elements or features. It should be noted that features, elements or components in the figures are not intended to be drawn to scale, emphasis being placed instead on demonstrating inventive principles and concepts.

During the last two decades, metaheuristics techniques have been applied to complicated optimization problems in different fields. The algorithms employ strategies that guide a subordinate heuristic method to find the near-optimal solution efficiency by intelligently searching space with different strategies. Among these metaheuristic methods, two computational methods that deal with the engineering optimization problems are the particle swarm optimization (PSO) and the genetic algorithm (GA). They are both pattern search techniques, which do not need to calculate the gradients of objective functions to optimize using methods such as quasi-Newton or gradient descent.

In this disclosure, single-objective and multi-objective optimizations with one or more metaheuristic algorithms can be applied to a set of sample cement data from VCCTL. A scoring system is created to evaluate cement based on Pareto front optimization results. A 1-D physical-chemical cement rotary kiln model is simulated with Matlab2016a solver and integrated with VCCTL and a multi-objective metaheuristic algorithm on a high performance computing cluster. Also disclosed is a computational framework that simulates cement and the cement plant intelligently based on user's needs and guides the optimal designs.

An integrated model is disclosed herein that provides a quantitative optimization tool for different energy efficiency measures addressed from cement plants and reduces energy, material consumption and greenhouse gas emissions without losing the performance of material.

In accordance with an embodiment, a system is provided for controlling operations of a cement kiln plant. In accordance with an embodiment, the system comprises first and second processing logic. The first processing logic is configured to perform an integrated modeling computer program comprising a Virtual Cement and Concrete Testing Laboratory (VCCTL) modeling computer program and a virtual cement plant (VCP) modeling computer program. The first processing logic receives output of the VCP modeling computer program and imports the output into the VCCTL modeling computer program. The second processing logic is configured to perform one or more multi-objective metaheuristic optimization computer programs on output of the integrated modeling computer program to adjust control parameters that are used to control the operations of the cement kiln plant.

Prior to discussing representative embodiments of the present disclosure, a discussion will be provided of current cement production modeling, cement hydration modeling and current optimization techniques in cement modeling.

### Cement Production.

Portland cement is the most common type of cement used in construction worldwide because of its affordability and the widespread availability of its constituent materials (e.g., limestone and shale). It is produced from the grinding of clinker, which is produced by the calcination of limestone and other raw minerals in a cement rotary kiln. Combining Portland cement with water causes a set of exothermic hydraulic chemical reactions that result in hardening and ultimately the curing of placed concrete.

According to United States Geological Survey (USGS), U.S. cement and clinker production in 2015 was 82.8 million tons and 75.8 million tons, respectively. U.S. ready mixed concrete production is 325 million tons. The production of cement and concrete consumes significant amount of energy. The associated energy assumption accounts for 2040% of the total cost.

In 2008, the U.S. cement industry spent $1.7 billion on energy alone, with electricity and fuel costing $0.75 billion and $0.9 billion, respectively. Cement production contributes 4% of the global industrial carbon dioxide (CO₂) emission. Among the emissions, 40% of CO₂ comes from the consumption of fossil fuels, 50% comes from calcination/decomposition of limestone inside the cement kiln, and 10% comes from transportation of raw meal and electricity consumption. During the cement and concrete production, the clinker production process inside the cement rotary kiln consumes more than 90% of the total energy use and all of the fuel use. For the modern cement plant, coal and coke have become principal fuel, which took place of natural gas in 1970s.

Currently, the industry is seeking different energy efficiency technologies to reduce these energy costs. The challenge lies in reducing production costs and energy consumption without negatively affecting product quality. The energy efficiency can be measured through multiple technologies including finer raw meal grinding, multiple preheater stages, combustion improvement, lower lime saturation factor, cement kiln shell heat loss reduction, optimization of location of cement factory for transportation cost reduction and high efficient facility such as roller mills, fans, motors, which means there is ample room for energy efficiency improvement. Among the energy-efficient technologies in cement production, fuel combustion improvement is an important consideration because it costs most of the energy (>50%) and produces most of the emissions (>40%). There are two types of rotary cement kilns: wet and dry. Wet kilns are typical longer (200 m) than dry kilns (50-100 m) in order to consider evaporation of water. Dry-type rotary kilns are more thermally efficient and common in the industry. There are four regions in a kiln: Preheating/Drying, Calcining/Decomposition, Burning/Clinkerizing, and Cooling. Precalciners are typically utilized to dry kilns to improve thermal efficiency, which allows for shorter kilns. In the present disclosure, dry-type rotary kilns are modeled.

Prior research has produced mathematical models to simulate thermal energy within the cement kiln and clinker formation to characterize the operation parameters, temperature profiles, clinker formation and energy consumption in the design. Due to the complexities of rotary kiln modeling, there is no single, universal model developed in research or commercial use. The oldest cement kiln model is a dynamic model that predicts the temperature file of freeboard gas, bulk bed and internal wall and the species compositions of each clinker product as they progress along the kiln. Different from other models, this model does not give a steady-state solution inside of the kiln. The formulations of wall temperature profiles and species mass fractions are functions of time. Partial differential equations are built to calculate temperature and species mass fraction at different stage.

For models applying a steady-state solution, there exists two types of one-dimensional models. The first type is a two-point boundary value problem, where the inlet temperature profiles of freeboard gas and bulk bed are given. From the solution of a series of ordinary differential equations, the temperature profiles and species mass fraction along the kiln are solved numerically. The second type incorporates coupled three-dimensional CFD models of the burner for freeboard gas profile and clinker chemistry due to the complexity of three-dimensional nature of flow generated from a burner.

In accordance with a representative embodiment of the present disclosure, a steady-state one-dimensional kiln model is applied because of its flexibility of parameters and computational availability for solvers in MATLAB paired with a high-performance cluster. Mathematical formulations are covered below in more detail. This one-dimensional physical-chemical kiln model is developed to simulate the behavior of the virtual cement plant (VCP). VCP is then coupled with VCCTL and a metaheuristic optimization tool for an integrated optimized computational model that predicts measures of performance and sustainability.

### Formulation of 1D Physical-Chemical Model of a Rotary Cement Kiln.

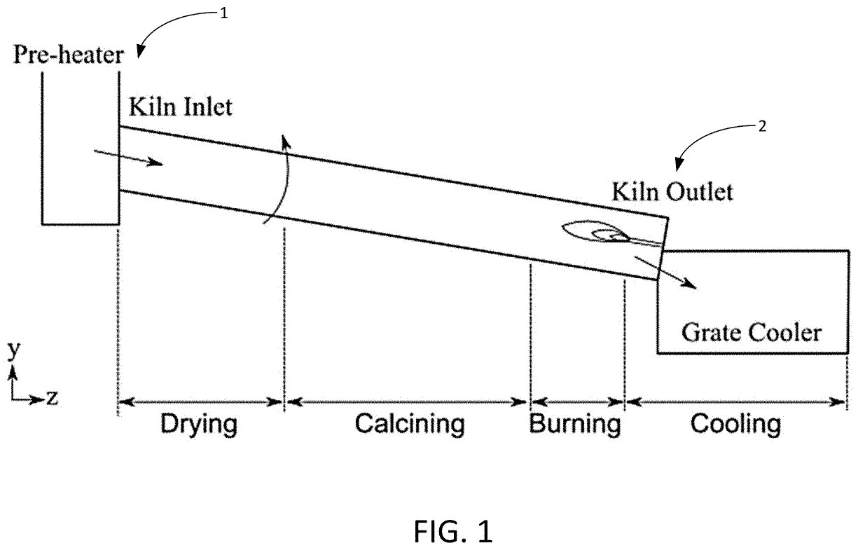

A rotary cement kiln is large equipment that converts raw meal to cement clinkers. FIG. 1 shows a schematic diagram of a rotary cement kiln. Raw meal enters at the higher end 1 with a certain solid flow rate. Fuel (coal, natural gas or petroleum coke) enters at the lower end 2. There are four main processes in the rotary kiln: drying, calcining, burning and cooling. First, the raw materials are preheated and dried to reduce moisture of the mixture for calcination. Then the limestone (CaCO₃) is calcined into calcium oxide (also known as free lime) and carbon dioxide (CO₂). After the calcination, a series of solid-solid and solid-liquid chemical reactions happens to form clinker. During this burning process, the temperature inside the kiln reaches its the highest. Alite (C₃S) and belite (C₂S) are formed from free lime. Coating also happens in this stage because of the presence of liquid. After the burning process, the hot clinkers are transported into a cooler for fast cooling. After that, the clinkers are grinded with cement mill and some additives (such as gypsum and limestone) are added based on the specification of users to get the final cement. Table 1 shows the name and chemical formula of raw meal and clinkers.

TABLE 1
Raw meal components and clinker phases.

| Type | Name | Chemical Formula |
|---|---|---|
| Raw meal | Calcium carbonate | CaCO₃ |
| | Silicon dioxide (Silica) | SiO₂ |
| | Aluminium oxide (Shale) | Al₂O₃ |
| | Ferrate oxide | Fe₂O₃ |
| Clinker | Tricalcium silicate (Alite) | C₃S (3CaO•SiO₂) |
| phases | Dicalcium silicate (Belite) | C₂S (2CaO•SiO₂) |
| | Tricalcium aluminate | C₃A (3CaO•Al₂O₃) |
| | Tetracalcium aluminoferrite | C₄AF (4CaO•Al₂O₃•Fe₂O₃) |

In Portland cement production, rotary kilns are considered as the core for cement manufacturing plants. At the entry of kiln, grinded and homogenized raw material-comprised of limestone (CaCO₃), alumina (Al₂O₃), iron (Fe₂O₃), silica (SiO₂) and a small amount of other minerals-pass through a preheater for initial calcination. Inside the kiln, the formation of cement clinker occurs from a series of chemical reactions including limestone calcination/decomposition and clinker formation. Clinker is then cooled at the exit of the kiln and grinded to fine powder for package. During the entire cement production process, the production of clinker inside of the cement kiln consumes most of the thermal energy, which is about 90% of the total energy. 50-60% of the energy consumption is attributed to the combustion of fuel.

Multiple 2D and 3D physical chemical models exist in the literature. More recent research has focused on creating a simplified 1D model, which is more computationally efficient. In accordance with a representative embodiment, 1D kiln model is applied that couples the heat-balance equation and the clinker chemical reaction rate equations to calculate the temperature of the different components of the kiln and the mass fraction for each phase of clinker production at steady state.

### Heat Transfer Equations.

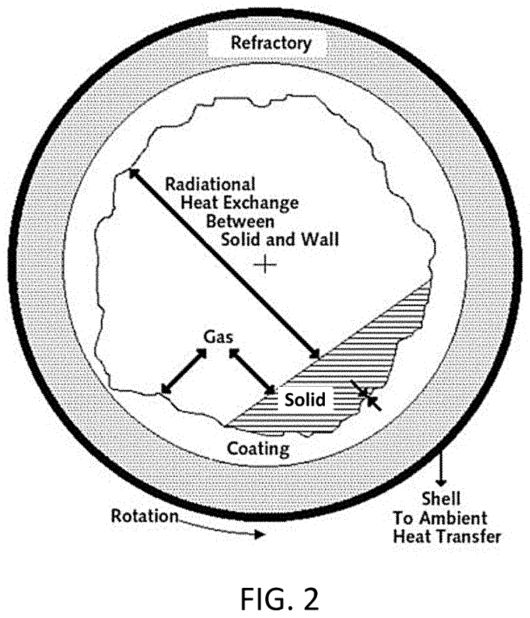

For the kiln model, three types of heat transfer, namely, radiation, convection and conduction, happen inside and outside of the kiln simultaneously. The interactive heat transfer happens between the gas phase and the solid phase, the gas phase between the wall, the solid and the wall. FIG. 2 shows a cross-section of the kiln depicting these three types of heat transfer.

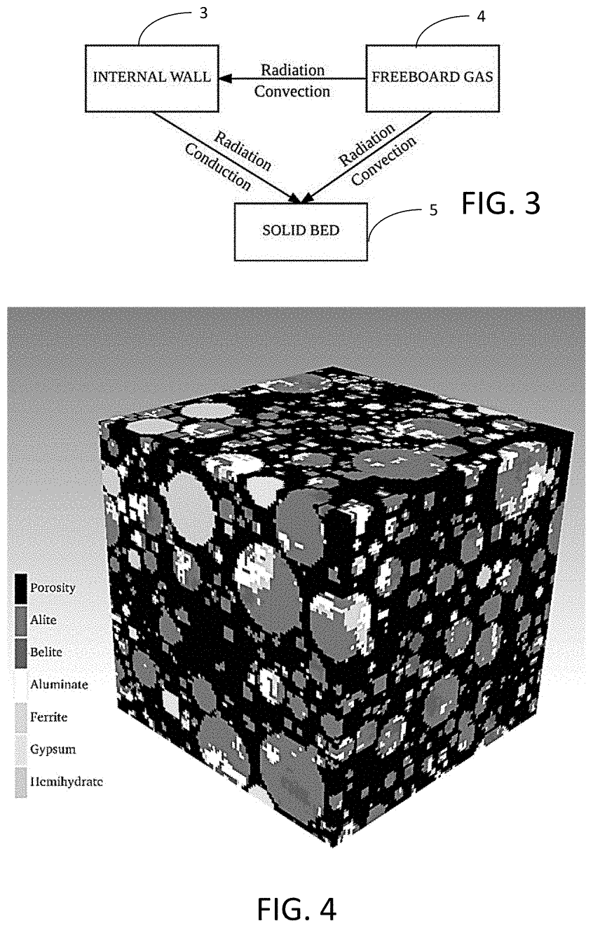

A group of heat equations including conduction from internal wall to solid bed, convection from freeboard gas to solid bed, convection from freeboard gas to internal wall, radiation from freeboard gas to solid bed, radiation from freeboard gas to internal wall and radiation from wall to solid have been developed to investigate the heat transfer. FIG. 3 is a diagram that shows the heat transfer between internal wall 3, freeboard gas 4 and solid bed 5 inside of the cement rotary kiln.

First, Equation 1 expresses the general energy balance of a steady-state, steady-flow model.

Q_{net,in}−Ŵ_{net,out}=Σ\dot{m}ₒᵤₜhₒᵤₜ−Σ\dot{m}ᵢₙhᵢₙ Eq. 1

Equations 2 to 9 express the formulation describing each of the heat transfer variables inside of the kiln based on the previous heat transfer knowledge and numerical models for a rotary kiln.

The conduction heat transfer happens when two objects are in contact. Inside of the kiln, conduction happens between the solid and the internal wall from direct contact between them. Q_{cwb} is expressed as the conduction heat transfer between the internal wall and the solid bed.

$${Q}_{cwb} = {h}_{cwb} {A}_{cwb} ( {T}_{W} - {T}_{B} ) \qquad Eq . 2$$

$${h}_{cwb} = 11.6 ( \frac{{k}_{b}}{{A}_{cwb}} ) {( \frac{ω {R}^{2} T}{{a}_{B}} )}^{0.3} \qquad Eq . 3$$

where A_{cwb} is the conduction area between the internal wall 3 and the solid bed 5, which is the product of the solid bed arc length and kiln length. Convection and radiation areas are calculated in similar ways. k_{b} is the thermal conductivity of the solid bed, ω is the rotational speed of the kiln, and R is the radius of the kiln. All of the parameters mentioned herein are listed below in the List of Abbreviations.

### LIST OF ABBREVIATIONS

A_{cgb} Convection area internal gas to bulk bed (m)
A_{cgw} Convection area internal gas to internal wall (m)
A_{cwb} Conduction area internal wall to bed (m)
A_{rgb} Radiation rea internal freeboard gas to bulk bed (m)
A_{rgw} Radiation area internal freeboard gas to internal wall (m)
A_{rwb} Radiation area internal wall to bulk bed (m)
Aₛ Area of bed segment (m)
Aₛₕ Area of steel shell (m)
Aᵢ Initial mass fraction of Al₂O₃ at inlet of the kiln
Aⱼ Pre-exponential factor for reaction (1/s)
AR Alumina ratio
Cp_{b} Specific heat of bulk bed (J/kg·K)
Crₘₐₓ Maximum coating thickness (m)
Dₑ Hydraulic diameter of kiln (m)
D Diameter of kiln (m)
dₙ Normalized Pareto front distance
Eⱼ Activation energy for j^{th} reaction (J/mol)
E₀ Minimum allowable modus
Fᵢ Initial mass fraction of Fe₂O₃ at inlet of kiln
fᵢ Objective function
h_{egb} Convection heat transfer coefficient freeboard gas to bed (W/m²·K)
h_{egw} Convection heat transfer coefficient gas to internal wall (W/m²·K)
h_{cwb} Conduction heat transfer coefficient from wall to bed (W/m²·K)
h_{csa} Convective heat transfer coefficient from shell to air (W/m²·K)
kₐ Thermal conductivity of air (W/m·K)
A_{b} Thermal conductivity of bulk bed (W/m·K)
k_{g} Thermal conductivity of fluid (W/m·K)
k₁ Reaction rate CaCO₃ (1/s)
k₂ Reaction rate C₂S (1/s)
k₃ Reaction rate C₃S (1/s)
k₄ Reaction rate C₃A (1/s)
k₅ Reaction rate C₄AF (1/s)
LSF Lime saturation factor
Pₑ Probability of non-exceedance
Q_{cgb} Convection heat transfer freeboard gas to bulk bed (W/m)
Q_{cgw} Convection heat transfer freeboard gas to internal wall (W/m)
Q_{cwb} Conduction heat transfer internal wall to bulk bed (W/m)
Q_{rgb} Rediation heat transfer freeboard gas to bulk bed (W/m)
Q_{rgw} Rediation heat transfer freeboard gas to internal wall (W/m)
Q_{rwb} Rediation heat transfer internal wall to bulk bed (W/m)
Q′ Heat gained by bulk bed due to heat transfer (Win)
qₑ Heat generated by chemical reactions (W/m³)
R_{g} Universal gas constant (J/mol·K)
R Internal radium of kiln (m)
S_{comb} Combining score
Sᵢ Initial mass fraction of SiO₂ at inlet of the kiln
SR Silica ratio
T_{g} Freeboard gas temperature (K)
T_{b} Bulk bed temperature (K)
T_{w} Internal wall temperature (K)
T₀ Temperature of atmosphere (K)
Tₛₕ Temperature of steel shell (K)
Vᵢ^{k+1} Velocity of i^{th} particle at k^{th} generation
v_{g} Velocity of bulk bed (ash)
xᵢ^{k+1} Position of i^{th} particle at k^{th} generation
Yₙ Mass fraction of n^{th} species
α_{b} Buk bed thermal diffusivity (m²/s)
αₛ Absorptivity of freeboard gas
β Angle of repose (rad)
ε_{b} Emissivity of bulk bed
ε_{g} Emissivity of freeboard gas
εₛₕ Emissivity of steel shell
ε_{w} Emissivity of internal wall
Γ Angle of fill of the kiln (rad)
μ_{g} Dynamic viscosity of freeboard gas (s/m²)
η Degree of solid fil
ω Rotational speed of kiln (rad/s)
ρ_{g} Density of freeboard gas (kg/m³)
ρₛ Density of solid (kg/m³)
σ Stefan-Boltzmann constant
v_{g} Kinematic viscosity of freeboard gas (m²/s)
ΔH_{CaCO3} Heat of reaction CaCO₃ (J/kg)
ΔH_{C2S} Heat of reaction C₂S (J/kg)
ΔH_{C3S} Heat of reaction C₃S (J/kg)
ΔH_{C3A} Heat of reaction C₃A (J/kg)
ΔH_{C4AF} Heat of reaction C₄AF (J/kg)

The radiative heat transfer happens by the emission of the electromagnetic radiation from the high-temperature object. Inside of the cement rotary kiln, both gas and the internal wall 3 emit the radiation. Q_{rwb} is expressed as the radiative heat transfer from the internal wall 3 to the solid bed 5.

$${Q}_{rwb} = σ {A}_{rwb} {ε}_{B} {ε}_{W} Ω ( {T}_{W}^{4} - {T}_{B}^{4} ) \qquad Eq . 4$$

$$Ω = \frac{\text{?}}{( 2 π - β ) R} \qquad Eq . 5$$

$$\text{?} \text{indicates text missing or illegible when filed}$$

Q_{rgb} is the radiative heat transfer from the freeboard gas 4 to the solid bed 5. Q_{rgw} is the radiative heat transfer from the freeboard gas 4 to the internal wall 3.

$${Q}_{rgb} = σ {A}_{rgb} ( {ε}_{b} + 1 ) \text{?} \qquad Eq . 6$$

$${Q}_{rgw} = σ {A}_{rgw} ( {ε}_{W} + 1 ) \text{?} \qquad Eq . 7$$

$$\text{?} \text{indicates text missing or illegible when filed}$$

The convection heat transfer happens between the object and its environment which happens between the freeboard gas phase and the wall, and between the gas phase and the solid. Q_{cgb} is the convective heat transfer from the freeboard gas 4 to the solid bed 5. Q_{cgw} is the convective heat transfer from the freeboard gas 4 to the internal wall 3. Calculations for h_{cgb} and h_{cgw} are known to be expressed as:

Q_{cgb}=h_{cgb}A_{cgb}(T_{G}−T_{B}) Eq. 8

Q_{cgw}=h_{cgw}A_{cgw}(T_{G}−T_{W}) Eq. 9

From Equations 2 through 9, the total heat flux received by the solid bed 5 from internal heat transfer is calculated as given by Equation 10:

$${Q}^{′} = \frac{{Q}_{cwb}}{{A}_{cwb}} + \frac{{Q}_{rwb}}{{A}_{rwb}} + \frac{{Q}_{rgb}}{{A}_{rgb}} + \frac{{Q}_{cgb}}{{A}_{cgb}} \qquad Eq . 10$$

From the above equations, the heat transfer between different components are related to each other. The temperature of the wall, the gas phase and the solid phase cannot be solved directly from the above equations.

### Clinker Formation.

Cement clinker formation is a complex chemical process in which numerous chemical reactions happen simultaneously. Each reaction has a separate thermodynamic condition. Typically, a series of five reactions has been applied to represent the complex chemical reactions inside cement kiln:

CoCO₃→CaO+CO₂ Eq. 11

2CaO+SiO₂→C₂S Eq. 12

C₂S+CaO→C₃S Eq.13

3CaO+Al₂O₃→C₃A Eq. 14

4CaO+Al₂O₃+Fe₂O₄→C₄AF Eq. 15

where the primary mineral constituents consist of tricalcium silicate C₃S (Alite), dicalcium silicate C₂S (Belite), tricalcium aluminate C₃A and tetracalcium aluminoferrite C₄AF. The main mineral in all of these compounds is calcium oxide CaO, which is acquired from the calcination and decomposition of limestone CaCO₃.

Inside the kiln, the solid material flows to the burner end of the kiln through the 2-5 degrees of inclination (shown in FIG. 1). Heated freeboard gas flows from the burner end to the entry on the top of solid bed material. From the heat transfer between the hot freeboard gas, solid bed material and the internal wall of the kiln (shown in FIGS. 2 and 3), a series of complex exothermic and endothermic reactions happens inside of the kiln for clinker formation. To simplify the process and make it convenient to analyze, only the major clinker formation chemical reactions (shown in Equations 11 through 15) are considered.

Table 2 shows the five major chemical reactions occurring inside of the cement kiln, which are used for clinker formation analysis in the model of the present disclosure. Different reactions happen at different temperature ranges, which are used to set the starting and ending points for each reaction in the model.

TABLE 2
Thermal information for clinker reaction (Darabi, 2007)

| | | Temperature | Enthalpy of |
|---|---|---|---|
| No. | Reaction | Range (K) | Reaction (J/kg) |
| 1 | CaCO₃ → CaO + CO₂ | 823-1233 | +1.782e6 |
| 2 | 2CaO + SiO₂ → C₂S | 873-1573 | −1.124e6 |
| 3 | C₂S + CaO → C₃S | 1473-1553 | +8.01e4 |
| 4 | 3CaO + Al₂O₃ → C₃A | 1473-1553 | −4.34e4 |
| 5 | 4CaO + Al₂O₃ + Fe₂O₄ → C₄AF | 1473-1553 | −2.278e5 |
| 6 | Clinker_{solid} → Clinker_{liquid} | >1553 | +6.00e5 |

In Table 2, positive sign indicates the reaction is endothermic and negative sign indicates the reaction is exothermic. Equation 16 below from gives the heat transfer from chemistry including heat absorbed from 1st and 3rd reactions and heat generated from 2nd, 4th and 5th reactions.

$${q}_{c} = \text{?} \qquad Eq . 16$$

$$\text{?} \text{indicates text missing or illegible when filed}$$

where Aᵢ, Fᵢ and Sᵢ are the input mass fraction for Al2O3, Fe2O3 and SiO2. ΔH is the heat of reaction. k is the reaction rate for jth reaction. Y is the mass fraction for the reactant or product participating in the j^{th} reaction. Based on the Arrhenius equation, reaction constants for the five chemical reactions inside of the kiln can be calculated from Equation 17.

$${k}_{j} = {A}_{j} exp ( - \frac{{E}_{j}}{{R}_{g} {T}_{b}} ) \qquad Eq . 17$$

where Aⱼ is the pre-exponential factor for the j^{th} reaction (1/s), Eⱼ is the activation energy for the j^{th} reaction (J/mol). R_{g} is the universal gas constant, which is 8.314 (J/g·mol·K). Table 3 lists the calculation of reaction rates and values for Aⱼ and Eⱼ.

TABLE 3
Reaction rate, pre-exponential factors and
activation energies for clinker reactions

| | | | Pre- | Activation |
|---|---|---|---|---|
| | | | exponential | Energy |
| | Reaction | | Factor (Aⱼ) | (Eⱼ) |
| No. | Constant | Reaction Rate | (1/s) | (J/mol) |
| 1 | k₁ | r₁ = k₁Y_{CaCO}_{₃} | 4.55e31 | 7.81e5 |
| 2 | k₂ | r₂ = k₂Y_{SiO}_{₂}Y_{CaO}² | 4.11e5 | 1.93e5 |
| 3 | k₃ | r₃ = k₃Y_{CaO}Y_{C}_{₂}_{S} | 1.33e5 | 2.56e5 |
| 4 | k₄ | r₄ = k₄Y_{CaO}³Y_{Al}_{₂}_{O}_{₃} | 8.33e6 | 1.94e5 |
| 5 | k₅ | r₅ = k₅Y_{CaO}⁴Y_{Al}_{₂}_{O}_{₃}Y_{Fe}_{₂}_{O}_{₃} | 8.33e8 | 1.85e5 |

Once the reaction rates are calculated, the production rate of each component can be calculated based on the reactions of the component participates. For example, CaO is the product of the 1^{st} reaction and the reactant of the 2^{nd}-5^{th} reactions. Therefore, the production rate for CaO is r1-r2-r3-r4-r5. Table 4 lists the reaction rates for all components in the five chemical reactions.

TABLE 4
Production rates for each component of reactions

| Component of Reactions | Production Rate |
|---|---|
| CaCO₃ | R₁ = −r₁ |
| CaO | R₂ = r₁ − r₂ − r₃ − r₄ − r₅ |
| SiO₂ | R₃ = −r₂ |
| C₂S | R₄ = r₂ − r₃ |
| C₃S | R₅ = r₃ |
| Al₂O₃ | R₆ = −r₄ − r₅ |
| C₃A | R₇ = r₄ |
| Fe₂O₃ | R₈ = −r₅ |
| C₄AF | R₉ = r₅ |
| CO₂ | R₁₀ = r₁ |

Mass fraction of each species can be calculated from material balance equations (2-18) from plug flow reactor with constant axial velocity at steady-state.

$${v}_{s} \frac{{dY}_{{CaCO}_{3}}}{dx} = - \frac{{M}_{{CaCO}_{2}}}{{M}_{CaO}} {k}_{1} {Y}_{{CaCO}_{2}} \qquad Eq . 19$$

$${v}_{s} \frac{{dY}_{CaCO}}{dx} = {k}_{1} {T}_{{CaCO}_{2}} - {k}_{2} {Y}_{{SiO}_{2}} - {k}_{3} {Y}_{CaO} {Y}_{{c}_{2} s} - {k}_{4} {Y}_{CaO}^{3} {Y}_{{Al}_{2} {O}_{2}} - {k}_{5} {Y}_{CaO}^{4} {Y}_{{Al}_{2} {O}_{2}} {Y}_{{Fe}_{2} {O}_{3}} \qquad Eq . 20$$

$${v}_{g} \frac{{dY}_{{CO}_{2}}}{dx} = \frac{{A}_{s}}{{A}_{g}} \frac{{ρ}_{s}}{{ρ}_{g}} \frac{{M}_{{CO}_{2}}}{{M}_{CaO}} {k}_{1} {Y}_{{CaCO}_{3}} \qquad Eq . 21$$

$${v}_{s} \frac{{dY}_{{SiO}_{2}}}{dx} = - \frac{{M}_{{SiO}_{2}}}{2 {M}_{CaO}} {k}_{2} {Y}_{{SiO}_{2}} {Y}_{CaO}^{2} \qquad Eq . 22$$

$${v}_{s} \frac{{dY}_{{Al}_{2} {O}_{3}}}{dx} = - \frac{{M}_{{Al}_{2} {O}_{2}}}{3 {M}_{CaO}} {k}_{4} {Y}_{CaO}^{3} {Y}_{{Al}_{2} {O}_{3}} - \frac{{M}_{{Al}_{2} {O}_{2}}}{4 {M}_{CaO}} {k}_{5} {Y}_{CaO}^{4} {Y}_{{Al}_{2} {O}_{2}} {Y}_{{Fe}_{2} {O}_{2}} \qquad Eq . 23$$

$${v}_{s} \frac{{dY}_{{Fe}_{2} {O}_{3}}}{dx} = - \frac{{M}_{{Fe}_{2} {O}_{3}}}{4 {M}_{CaO}} {k}_{5} {Y}_{CaO}^{4} {Y}_{{Al}_{2} {O}_{3}} \qquad Eq . 24$$

$${v}_{s} \frac{{dY}_{{C}_{3} S}}{dx} = \frac{{M}_{{C}_{2} S}}{2 {M}_{CaO}} {k}_{2} {Y}_{{SiO}_{2}} {Y}_{CaO}^{2} - \frac{{M}_{{c}_{2} s}}{{M}_{CaO}} {k}_{3} {Y}_{CaO} {Y}_{{C}_{2} S} \qquad Eq . 25$$

$${v}_{s} \frac{{dY}_{{C}_{3} S}}{dx} = \frac{{M}_{{C}_{3} S}}{2 {M}_{CaO}} {k}_{3} {Y}_{CaO} {Y}_{{C}_{2} S} \qquad Eq . 26$$

$${v}_{s} \frac{{dY}_{{C}_{3} A}}{dx} = \frac{{M}_{{C}_{3} A}}{3 {M}_{CaO}} {k}_{4} {Y}_{CaO}^{3} {Y}_{{Al}_{2} {O}_{3}} \qquad Eq . 27$$

$${v}_{s} \frac{d \text{?}}{dx} = \frac{\text{?}}{4 {M}_{CaO}} {k}_{5} {Y}_{CaO}^{4} {Y}_{{Al}_{2} {O}_{2}} {Y}_{{Fe}_{2} {O}_{3}} \qquad Eq . 28$$

$$\text{?} \text{indicates text missing or illegible when filed}$$

After the calculations of the equations for the mass fraction of each component have been performed, the temperature of the solid bed can be calculated based on the mass fractions and the total heat received by the solid bed Q′, which is expressed in Equation 29 as:

$${v}_{s} {Cp}_{b} {A}_{s} \frac{d ( {ρ}_{b} {T}_{b} )}{dx} = {Q}^{′} {L}_{gcl} + {A}_{s} {q}_{c} - {S}_{{CO}_{2}} \qquad Eq . 29$$

The production rate for the mass fraction of each component in the reactions is related to the temperature of solid bed (Equations 16-28), and heat received by the solid bed is calculated from heat transfer (Equations 1-10). The heat transfer items and clinker chemistry items are coupled by Equation 29.

By solving the ordinary differential equations, Equations 1 to 29, the temperature and the mass fractions of each species inside of the kiln can be calculated simultaneously. The above equations can be integrated with the metaheuristic method to optimize the factor as the user requests.

### Heat Balance

Equation 30 from shows that the heat balance relation among shell, refractory and coating is satisfied for a kiln at steady state. The calculation for shell temperature is known and therefore will not be explained in detail in this section.

Q_{rgw}+Q_{cgw}−Q_{rwb}−Q_{cwb}=σAₛₕεₛₕ(Tₛₕ⁴−T₀⁴)+h_{csh}Aₛₕ(Tₛₕ−T₀) Eq. 30

The heat balance equation is applied to check the accuracy temperature profiles using the known Newton Raphson Method, as discussed below in more detail.

### Cement Hydration Modeling

The concrete research community has long sought to reduce its reliance on physical testing of Portland cements. However, advancements in computational modeling have yet to produce a widely accepted, purely numerical approach that performs as reliably and accurately as experimental methods (ASTM C109, ASTM C1702, ASTM C191).

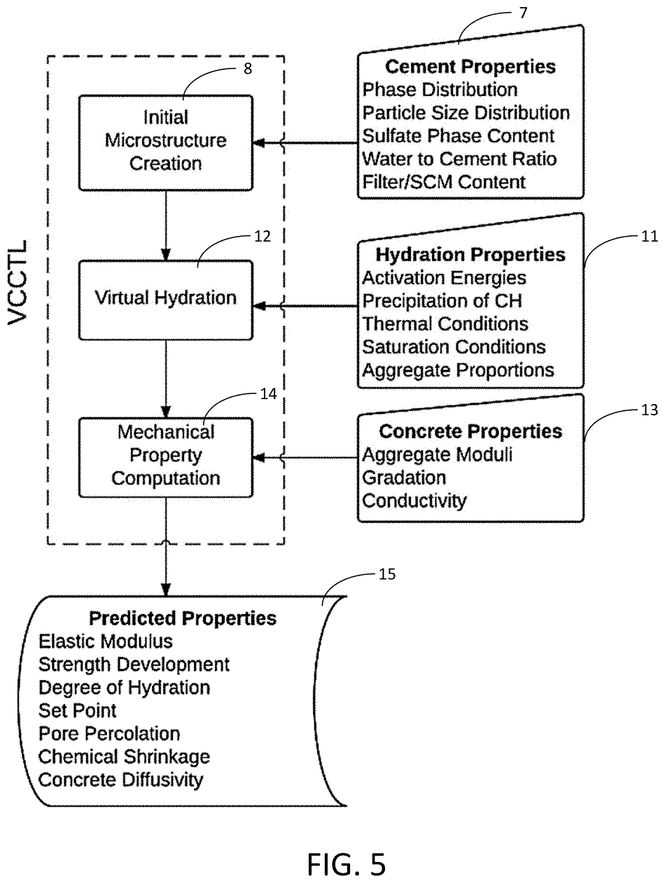

One of the longest standing efforts to create a numerical framework is the software known as the Virtual Cement and Concrete Testing Laboratory (VCCTL), which has been available for commercial use from the National Institute of Standards and Technology (NIST) for several years. The study model predicts the thermal, electrical, diffusional, and mechanical properties of cements and mortars from user-specified phase distribution, particle size distribution, water/cement ratio (w/c), among other parameters. FIG. 4 shows a three-dimensional (3-D) image of the initial microstructure from VCCTL. FIG. 5 illustrates a flow diagram of the VCCTL model algorithm in accordance with a representative embodiment, which is a three-stage process:
1. Volume and surface area fractions of the four major cement phases (alite, belite, aluminate and ferrite) are obtained from X-ray powder diffraction, scanning electron microscopy, and multispectral image analysis to create a 3-D microstructure of unreacted paste (FIG. 4) that is comprised of Portland cement, fly ash, slag, limestone and other cementitious materials. These steps are represented by blocks 7 and 8 in FIG. 5.
2. Kinetics and thermodynamics of Portland cement hydration are simulated under specified curing conditions including adiabatic and isothermal heating, producing virtual models of the material that can be analyzed for multiple properties, including linear elastic modulus, compressive strength, and relative diffusion coefficient. The rate of hydration and resulting products are governed largely by the relative concentrations of the four major constituents of Portland cement: alite (C₃S), belite (C₂S), aluminate (C₃A), and ferrite (C₄AF). The most reactive compounds are C₃A and C₃S. For strength development, the calcium silicates provide most of the strength in the first 3 to 4 weeks though, both C₃A and C₂S contribute equally to ultimate strength. C₂S hydrates in a similar way with C₃S; however, C₂S hydrates much slower since it is a less reactive compound. Consequently, the amount of heat liberated by the hydration of C₂S is also lower than the amount of heat C₃S liberates. Gypsum is introduced into the raw meal to slow the early rate of hydration of C₃A. These steps are represented by blocks 11 and 12 in FIG. 5.
3. Finite element analysis of the resultant virtual microstructure gives the elastic modulus (E), as indicated by blocks 13, 14 and 15.

### Current Optimization Techniques in Cement and Concrete

As discussed above, cement compounds play important roles in the hydration process. Changing the proportion of each constituent compound, adjusting other factors such as particle size or fineness, for example, can vastly change the mechanical and thermal properties of the hydration process, and ultimately the final product. Due to the various factors in cement production and hydration, it is important and efficient to develop optimal computational models reflecting the effect of each factor and giving directions based on specific performance instead of conducting a large amount of physical testing.

As the awareness of the potential of cement and concrete to achieve higher performance grows, the problem of designing cement and concrete to exploit the possibilities has become more complex. In the past few years, statistical design of experiments, such as the response surface approach, were developed to optimize cement and concrete mixtures to meet a set of performance criteria at the same time with reducing computational cost. Those performance criteria within cement and concrete properties includes time of set, modulus of elasticity, viscosity, creep and shrinkage, heat of hydration and durability. Considering that cement and concrete mixtures consist of several components, the optimization should be able to take into account several attributes at a time. However, known statistical methods become inefficient due to the excessive number of trial batches for each simulation to find optimal solutions.

Optimization Techniques in Cement and Concrete in Accordance with the Inventive Principles and Concepts

In accordance with representative embodiments of the present disclosure, a metaheuristic optimization method is applied, which is an iterative searching process that guides a subordinate heuristic by exploring and exploiting the search space intelligently with different learning strategies. Optimal solutions are found efficiently with this technique. Those methods have had widespread success and become influential methods in solving difficult combinational problems during the last several decades in engineering, mathematics, economics and social science. Some of the most popular metaheuristic algorithms include genetic algorithms, particle swarm optimization, neutral networks, harmony search, simulated annealing, tabu search, etc.

Particle Swarm Optimization (PSO) is a population-based metaheuristic. This metaheuristic algorithm mimics swarm behavior in nature, e.g., the synchronized movement of flocking birds or schooling fish. It is straightforward to implement and is suitable for a non-differentiable and discreditable solution domain. A PSO algorithm guides a swarm of particles as it moves through a search space from a random location to an objective location based on given objective functions.

Another search method is the genetic algorithm (GA), which is developed from principles of genetics and natural selection. GA encodes the decision variables of a searching problem with a series of strings. The strings contain information of genes in chromosomes. GA analyzes coding information of the parameters. A key factor for this method is working with a population of designs that can mate and create offspring population designs. For this method to work, fitness is used to select the parent populations based on their objective function value, and the offspring population designs are created by crossing over the strings of the parent populations. Selection and crossover form an exploitation mechanism seeking for optimal designs. Furthermore, the mutations are added to the string as an element of exploration.

A multi-objective optimization problem (MOOP) considers a set of objective functions. For most practical decision-making problems, multiple objectives are considered at the same time to make decisions. A series of trade-off optimal solutions instead of a single optimum, is obtained in such problems. Those trade-off optimal solutions are also called Pareto-optimal solutions.

For the representative embodiment described herein for cement and concrete modeling, multi-objective optimizations are applied because several performance criteria of cement and concrete need to be considered at the same time. As discussed above, VCCTL utilizes a number of input variables to execute a complete virtual hydrated cement model for analyzing mechanical and material properties. There are a large number of potential combinations for inputs (˜106). It can take one hour to run each combination on VCCTL with a high-performance computing cluster. Therefore, a blind search for specified performance criteria is not practical. Metaheuristic techniques, however, provide a reasonable direction for searching through a large feasible domain, which is efficient and suitable for the inputs and outputs from VCCTL. Both PSO and GA solve MOOPs to give a Pareto frontier, which consists of optimal solutions. Elitism strategy can be applied to keep the best individual from the parents and offspring population. Also, the idea of a non-dominated sorting procedure can be applied to the PSO to solve the MOOP and increase the efficiency of optimization.

In accordance with representative embodiments, metaheuristic algorithms are applied based on VCCLT to solve MOOP in virtual cement, as will now be described in detail.

### Metaheuristic Algorithms Applied to Virtual Cement Modeling

This portion of the present disclosure presents the application of metaheuristic algorithms on VCCTL to optimize chemistry and the water-cement ratio of cement and mortar. The present disclosure adopts a forward-looking view that this goal will be reached, turning then to how its full investigative power can be applied to characterize a broad range of cements and hydration conditions. It successfully demonstrates that a multi-objective metaheuristic optimization technique can generate the Pareto surface for the modulus of elasticity, time of set and kiln temperature for approximately 150,000 unique cements that encompass the clear majority of North American cement compositions in ASTM C150 (Cement). Insofar as the hydration model is accurate, the benefit of applying large-scale simulations to characterize the strength, durability and sustainability of an individual cement relative to a broad range of cement compositions is shown.

The present disclosure describes the hydration study model in VCCTL, the metaheuristic algorithm in accordance with the inventive principles and concepts, and different case studies that demonstrate the utility of metaheuristic algorithms to find optimal solutions and Pareto analysis on Portland cements. Convergence is discussed to assist users replicating this approach. Finally, the present disclosure demonstrates that tri-objective Pareto analysis is a flexible and objective tool to rate cements and offer remarks on the potential of this approach to solve much large combinatorial problems arising from the introduction of other variables such as cement fineness and aggregate proportions.

### Methodology

The VCCTL algorithm was ported to a High Performance Computer (HPC), operating up to 500 cores for nearly one month to complete 149,572 unique simulations based on the input bounds shown in Table 5. Cement phases and w/c were discretized into 10 and 15 equally spaced intervals, respectively, with the constraint that the mass fractions for all phases sum to unity. These data were archived for reuse during algorithm development (thus preventing the need to rerun VCCTL) and for the case studies discussed below that compare the Pareto Front technique to the fully enumerated solution space.

TABLE 5
Lower and upper bounds of VCCTL inputs

Mass Fraction

| Input | Lower Bound | Upper Bound |
|---|---|---|
| Water to Cement Ratio (w/c) | 0.20 | 0.53 |
| Alite (C₃S) | 0.50 | 0.70 |
| Belite (C₂S) | 0.15 | 0.37 |
| Ferrite (C₄AF) | 0.05 | 0.20 |
| Aluminate (C₃A) | 0.03 | 0.10 |
| Gypsum | 0.00 | 0.06 |
| Anhydrite | 0.00 | 0.04 |
| Hemihydrate | 0.00 | 0.04 |

Once a completed VCCTL simulation is done, a set of outputs for hydrated cement paste models is created from the hydration, transport and mechanical properties. Model data applied in the present disclosure were the (a) output seven-day elastic modulus, (b) output time of set of the hydrated paste, and (c) a proxy for kiln temperature, the ratio of inputs alite (C₃S) and belite (C₂S).

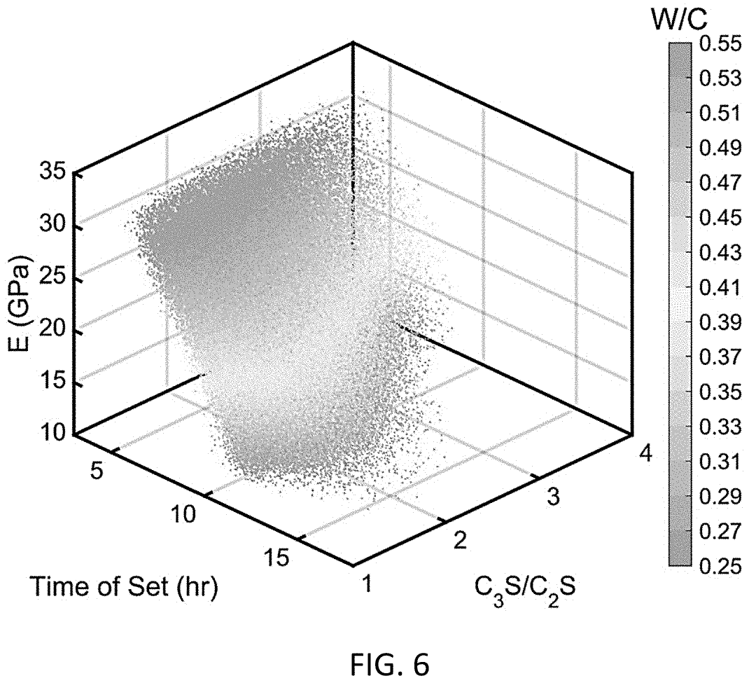

A brief introduction for the four outputs is as follows: (a) seven-day elastic modulus is calculated directly from the 3-D image using a finite element method. The elastic modulus of the cement paste is directly related to the stiffness of a concrete made with that paste and provides an indication of the relative stiffness for different cement compositions and water cement ratios. The elastic modulus can also be used to calculate the compressive strength of concrete, which is considered as a valuable design parameter in many applications; (b) Time of set is the final setting time of the concrete. Setting refers to the stage changing from a plastic to a solid state, also known as cement paste stiffening. It is usually described in two levels: initial set and final set. Initial set happens when the cement paste starts to stiffen noticeably. Final set happens when the cement has hardened enough for load. To determine the setting time, measurements are taken through a penetration test; (c) VCCTL does not model cement production, thus alite:belite was chosen based on the assumption that they form at higher and lower kiln temperatures, which represent the embodied energy in the cement production process due to the direct relationship between embodied energy and carbon content. FIG. 6 plots values for each cement, with marker color corresponding to the w/c (shown on the right).

Seen as a whole, the results compare well with expected behavior. The range of E, time of set, and C₃S/C₂S are [11.1, 32.0] GPa, [3.2,17.4] hrs, and [1.2,3.9], respectively, which are acceptable ranges based on the bounds shown in Table 1. The model captures the effect of paste densifying as w/c decreases, which causes the modulus to increase. Further, the observed relationship between E and w/c matches the experimental measurements described previously. The modulus is also observed to increase proportionally with increasing C₃S/C₂S, which is consistent with past research that has shown alite is the primary silicate phase contributing to early strength development in Portland cement. The model also captures the decrease in time of set associated with a lower w/c, which increases the rate of hydration. The setting of paste occurs as the growth of hydration solids bridges the spaces between suspended cement particles. Higher water to cement ratios result in larger spaces between particles, generally increasing the time needed for setting to occur, as well as the sensitivity of setting time to differences in cement composition.

Table 6 lists the structure of the VCCTL database for virtual cement. The database consisting of inputs and outputs of VCCTL for 149,572 different Portland cement compositions is sample data for metaheuristic optimization introduced in the following section.

TABLE 6
Database column identifier.

| | Column | Item |
|---|---|---|
| Inputs | 1 | Water to Cement Ratio |
| | 2 | Alite Mass Fraction |
| | 3 | Belite Mass Fraction |
| | 4 | Ferrite Mass Fraction |
| | 5 | Aluminate Mass fraction |
| | 6 | Gypsum Mass Fraction |
| | 7 | Anhydrite Mass Fraction |
| | 8 | Hemihydrate Mass Fraction |
| Outputs | 9 | 7-day Heat (kJ/kg) |
| | 10 | Time of Set (hours) |
| | 11 | Degree of hydration (%) |
| | 12 | 7-day Elastic Modulus (GPa) |

### Cement Optimization Based on Metaheuristic Algorithms

### Overview

Multiple objectives drive cement production (e.g., minimize kiln temperature while maximizing the modulus), thus a set of trade-off optimal solutions should be obtained instead of a single optimum. The solution is the so-called Pareto front, which is an envelope curve on the plane for two objectives and a surface in space for three objectives. The optimal solution set on a Pareto front are the set of solutions not dominated by any member of the entire search space. This is generally not the case for cements, however. For example, one composition may have a larger E than a second composition with a lower heat proxy than the first. All else being equal, neither cement dominates another in terms of quality without additional user input to differentiate the relative importance of each variable. Therefore, non-dominated solutions were selected by simultaneously comparing three objectives (described below) to evaluate the fitness (optimality) of each cement.

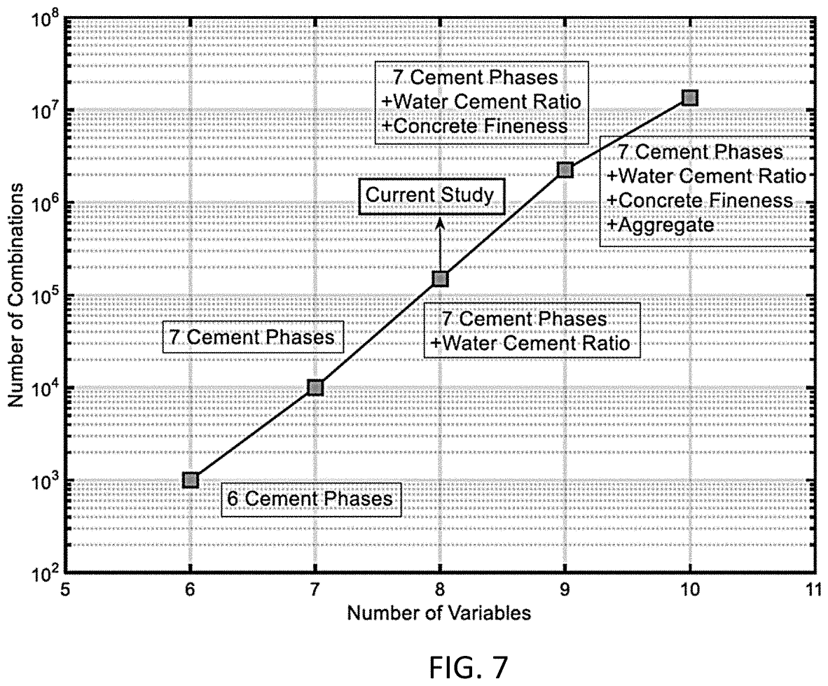

Another consideration in the analysis was the combinatorial explosion arising from studying larger variable sets. While the Pareto front can be calculated directly from enveloping VCCTL results for every unique combination of cement phase and w/c, it would generally be impractical for a problem larger than what this disclosure presents. Consider FIG. 7, which depicts the number of computer simulations as a function of the variable count. The current study (eight variables) utilized hundreds of cores on a HPC running nearly one month to complete. Adding one new variable (e.g., concrete fineness) would increase the run time by a factor of ten. Adding a second new variable would render the simulation impractical in most HPC infrastructures.

The realization that computational expense would ultimately be a significant barrier to implementation motivated the application of the multi-objective metaheuristic search algorithm described in the next section. The present disclosure demonstrates that it is possible to study the Pareto front of Portland cement with a vastly reduced number of simulations than what is needed to build a data-driven Pareto front, thus hopefully creating extensibility to larger combinatorial problems that will follow the study disclosed in the present disclosure.

Current cement and concrete optimization primarily applies statistical methods. In contrast, representative embodiments of the present disclosure apply metaheuristic optimization, which, as stated above, has shown widespread success in solving difficult combinational problems in other fields. Common methods include particle swarm optimization (PSO), genetic algorithms, harmony search, simulated annealing, and TABU search.

In accordance with a representative embodiment, the metaheuristic optimization involves applying PSO and GA because they are straightforward to implement and suitable for a non-differentiable and discretizable solution domain. Both methods are population-based metaheuristic approaches, which maintain and improve multiple candidate solutions by using population characteristics to guide the search.

To conduct a metaheuristic search, good solutions need to be distinguished from bad solutions. In accordance with an embodiment, solutions for each individual are evaluated from objectives such as seven-day modulus, time of set, heat proxy of each virtual cement from simulation results in VCCTL. In accordance with this embodiment, the elitism strategy (or elitist selection), known as the process to allow best individuals from current generation to next generation, is used by both search algorithms to guide the evolution of good solutions. The population size, which is defined by users, plays a valuable role in algorithms. It affects the performance of the algorithm: if too small, premature convergence will happen to give unacceptable solutions; if too large, a lot of computational cost will be wasted. The basic ideas and procedures of PSO and GA are explained below in detail.

### Pareto Front Generation Applying Particle Swarm Optimization

As is known, the PSO algorithm mimics swarm behavior in nature, e.g., the synchronized movement of flocking birds or schooling fish. Each particle (here the unique combination of phase chemistry and w/c) in the search space has a fitness value calculated from a user-specified objective function. During each iteration, the particle ‘velocities’ are updated to cause the swarm to move towards the better solution area in the search space. The procedure is as follows:
1. Initialize the particle positions xᵢ^{k=0} from the set: (w/c,C₃S,C₃S,C₄AF,C₃A,Gypsum,Anhydrite,Hemthydrate) drawing from the uniform distribution of each design variable within the bounds shown in Table 3-1, where i is the particle number and k is the generation
2. Copy xᵢ^{k=0} to Pᵢ^{k}, which are the best positions of each particle up to the current generation
3. Calculate the corresponding objective functions f₁^{k=0}(xᵢ), f₂^{k=0}(xᵢ), f₃^{k=0}(xᵢ), i.e., E, time of set and C₃S/C₂S from VCCTL
4. Randomly assign one of the non-dominated positions in the swarm to P_{g}^{k}. For example, consider the tri-objective case minimizing time of set and C₃S/C₂S and maximizing E. The variable xᵢ^{k=0} is a non-dominated position if and only if there is no xⱼ^{k=0}(j≠i) in the generation with one of the three characteristics below for min f₁−min f₂−max f₃ case:

f₁(xⱼ)≤f₁(xᵢ) and f₂(xⱼ)≤f₂(xᵢ) and f₃(xⱼ)>f₃(xᵢ)

f₁(xⱼ)≤f₁(xᵢ) and f₂(xⱼ)<f₂(xᵢ) and f₃(xⱼ)≥f₃(xᵢ)

f₁(xⱼ)<f₁(xᵢ) and f₂(xᵢ)≤f₂(xᵢ) and f₃(xⱼ)≥f₃(xᵢ) Eq. 31
5. If k=0, initialize the velocities to zero, vᵢ^{k=0}=0
6. If k>0, update the velocities of each particle with

Vᵢ^{k+1}+=wVᵢ^{k}+c₁r₁(Pᵢ^{k}−xᵢ^{k})+c₂r₂(P_{g}^{k}−xᵢ^{k}) Eq. 32

where c₁ and c₂ are the acceleration coefficients associated with cognitive and social swarm effects, respectively; r₁ and r₂ are random values uniformly drawn from [0,1], and w is the inertia weight, which represents the influence of previous velocity (L. Li et al., 2007). Based on trial and error, we selected both c₁ and c₂ to equal 0.8 respectively, and w decrease linearly from 1.2 to 0.1 over 500 generations
7. Update the new position of each particle t:

xᵢ^{k+1}=xᵢ^{k}+Vᵢ^{k+1} Eq.33
8. Calculate the three objective functions for each particle of the current generation (Eq. 3-2), and update Pᵢ^{k} with the non-dominated positions if it is better than Pᵢ^{k-1}
9. Update P_{g}^{k} by randomly assigning one of the non-dominated position in the swarm
10. Store and update non-dominated solution found from the current generation in an external archive (known as elitist selection)
   Steps 6-10 can be repeated until the algorithm converges, as will be described below in more detail.

### Pareto Front Generation Applying Genetic Algorithm

Based on principles of genetics in evolution and natural selection, a Genetic Algorithm was developed where strings containing the information of the design variables are created, which imitates DNA containing gene information in nature. Once the optimization problem for virtual cement is encoded in a chromosomal manner and objectives are calculated to evaluate the fitness of the solutions, GA starts to evolve a solution using the following steps:
1. Similar with PSO, initialize the population set, {w/c, C3S, C2S, C4AF, C3A, Gypsum, Anhydrite, Hemihydrate}, by randomly generating from the uniform distributed searching space of design variable with bounds shown in Table 5
2. Evaluate the fitness of each candidate solution by calculating and comparing the objectives with Equation 31
3. Select solutions with better fitness based on Step 2 to assign more good solutions for next generation. Tournament selection, is used in current study (Burke & Kendall, 2005)
4. Conduct crossover by combining parts of the parent population to create offspring population
5. Randomly modify one or two points at the parent chromosomes during the crossover, which mimics the gene mutation to give more random in the nearing space to candidate solution
6. After steps 3-5, replace parent population by offspring population. Replacement: The offspring population created by selection, crossover and mutation replaces the original parental population. One of the most popular replacement techniques, Elitism (Deb, Pratap, Agarwal, & Meyarivan, 2002) is applied for replacement in current study
7. Repeat steps 2 to 6 until algorithm converges

### Case Studies

### Example 1: Single Objective Optimum for Modulus

To verify whether the optimization method is appropriate to solve optimization problems based on VCCTL, a single-objective optimization is conducted as the first case study. Since the 7-day elastic modulus (E) factor is directly related to the strength of cement, it is selected as the objective to be optimized to a user-specified value. From the output database of VCCTL, the range of the 7-day elastic modulus is from 11.1 to 32 GPa which is consistent with literature. To demonstrate this case, the 7-day elastic modulus is optimized to a target value Etarget of 15 GPa. Other target values could also be selected based on user's specifications. In this way, the single objective function of this problem is |E−E_{target}|, which should be minimized to get the optimal solution.

For this single-objective problem, the PSO algorithm is applied. The procedure was illustrated above. For this problem, the particle population size is set to 100, balancing between the number of generations needed to converge and computational cost. And the optimization process is considered converged when the objective function is less than 10′.

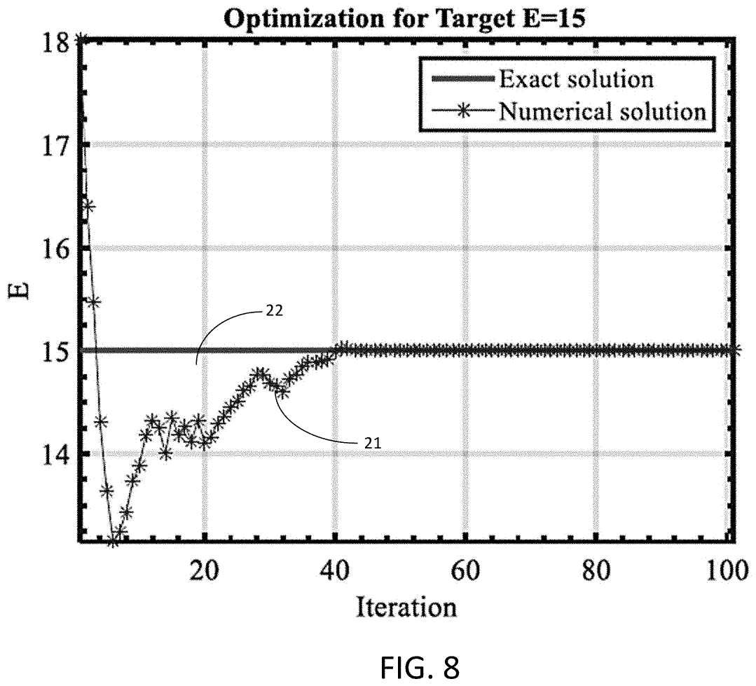

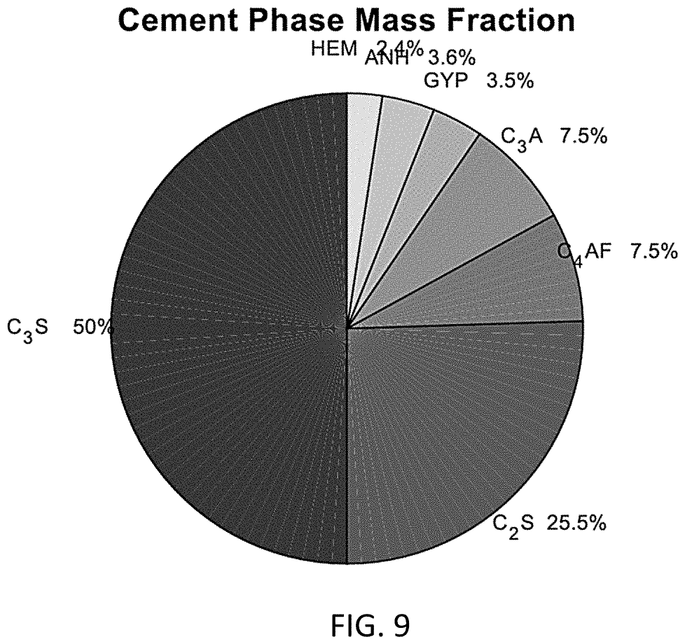

FIG. 8 is a plot of E as a function of iteration with PSO and shows the values of the objective function for 100 iterations. As seen in FIG. 8, the entire optimization process, which is represented by plot 21 in FIG. 8, converges after about 40 iterations, where the 7-day elastic modulus is closest to E_{target}. The exact solution is also calculated and represented in FIG. 8 by line 22, which is the same value after the PSO method converges. Furthermore, FIG. 9 shows the distribution of each cement phase at the optimal solution calculated by the PSO method. For this case, it takes 3,800 times run in VCCTL to find the target modulus, which is the product of the particle swarm size (100) and the number of generations needed for convergence (40) deducting repeated individuals during searching for each generation.

### Example 2: Bi-Objective Pareto Front for Modulus and Time of Set

Multiple objectives drive cement production, thus a set of trade-off optimal solutions, should be obtained instead of a single optimum. Therefore, the proposed approach is framed as a multi-objective optimization problem (MOOP) that calculates the Pareto front, an envelope curve on the plane for a bi-objective case or a surface in space for a tri-objective case that encompasses all optimal solutions. The optimal solution set on the Pareto front is defined as a set of solutions that are not dominated by any member of the entire search space (shown in Equation 31). The Pareto front is visualized by connecting all of the non-dominated solutions.

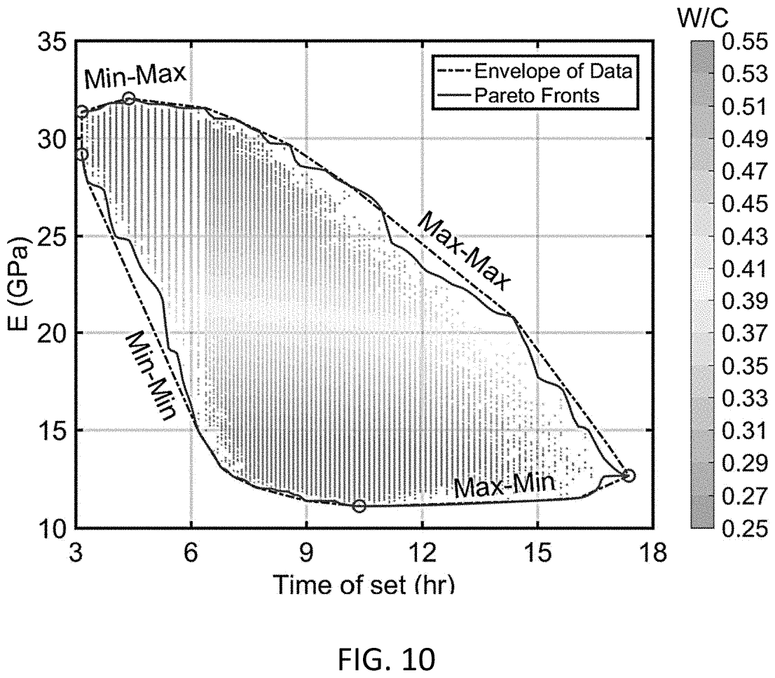

The second case study calculates the Pareto front (and the inherent trade-off) of E and time of set. FIG. 10 is a plot of E as a function of time of set of Pareto fronts of four different bi-objective optimization scenarios without constraints compared with the data envelope. Exploring the Pareto fronts with the PSO decreases the computational cost by more than 70%. FIG. 10 shows the full simulation outputs, with the Pareto fronts superimposed for four cases: [1] minimize time of set and minimize E (Min-Min); [2] minimize time of set and maximize E (Min-Max); [3] maximize time of set and minimize E (Max-Min); and [4] maximize time of set and maximize E (Max-Max). The Pareto fronts obtained from the PSO were generated using 30% of the simulations needed to fully enumerate the sample space. Further, the curves coincide for the majority of the data envelope, varying by less than one hour and 5 GPa on the horizontal and vertical scales, respectively, in the absolute worst case. This example, while simple, demonstrates the potential of the PSO generated Pareto front as a substitute for bulk analysis.

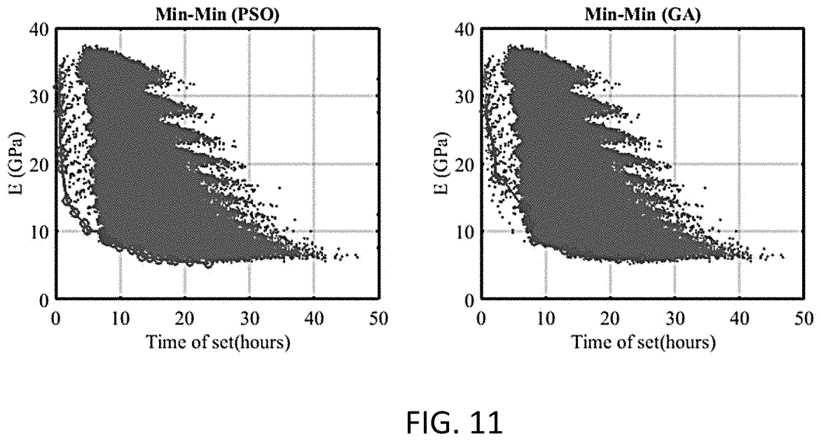

A Genetic Algorithm (GA) was also verified to work for the bi-objective optimization problem. The bi-objective optimization results obtained from PSO and GA are compared. From FIG. 11, it can be seen that the results from both methods have similar Pareto front curves and match very well. This proves that both the PSO and GA methods are appropriate to solve the bi-objective optimization problem of the VCCTL. Also, the converging speed and computational time are also compared between these two methods with the same population size (1000). The comparison results are shown in Table 7. As shown in Table 7, PSO and GA require a different number of generations to converge to the optimal solution. It takes about 200 generations to converge for the PSO method, while only about 30 generations for the GA method with a population size of 1000. On other hand, it takes 80 times longer to execute the GA method than the PSO method. In summary, for this case, GA converges in fewer generations than PSO, but requires more time to execute.

TABLE 7
Comparison of computational cost of PSO and GA.

| Optimization | Population | Number of | Time to run |
|---|---|---|---|
| techniques | size | iteration | (sec) |
| PSO | 1000 | 200 | 10.9 |
| GA | 1000 | 30 | 814.9 |

### Example 3: Tri-Objective Optimization of Modulus, Time of Set and Heat Proxy

Having verified both of the optimization algorithms for bi-objective optimization, a more complicated problem is introduced to demonstrate the application of these methods. From the knowledge of cement materials, cement paste with less setting time will develop strength earlier. Thus, time of set of the cement needs to be minimized. As mentioned earlier, C₃S is the most reactive compound among the cement constituents, whereas C₂S reacts much more slowly. In this way, the compounds are the most abundant within the Portland cement system with C₃S (alite) needing higher kiln temperatures to form, while the C₂S phase forms at lower kiln temperatures. Thus, C₃S/C₂S should be minimized to ensure less energy is used to create the cement, liberate less heat and less greenhouse gas emissions. The 7-day elastic modulus needs to be maximized to obtain more strength for cement paste.

In the third example, objective functions for C₃S/C₂S, time of set, and 7-day E are optimized simultaneously to identify the Pareto fronts bounded by three cases: [1] minimize C₃S/C₂S, minimize time of set, and maximize E (Min-Min-Max); [2] minimize C3S/C2S, minimize time of set, and minimize E (Min-Min-Min); and [3] maximize C3S/C2S, maximize time of set, and maximize E (Max-Max-Max).

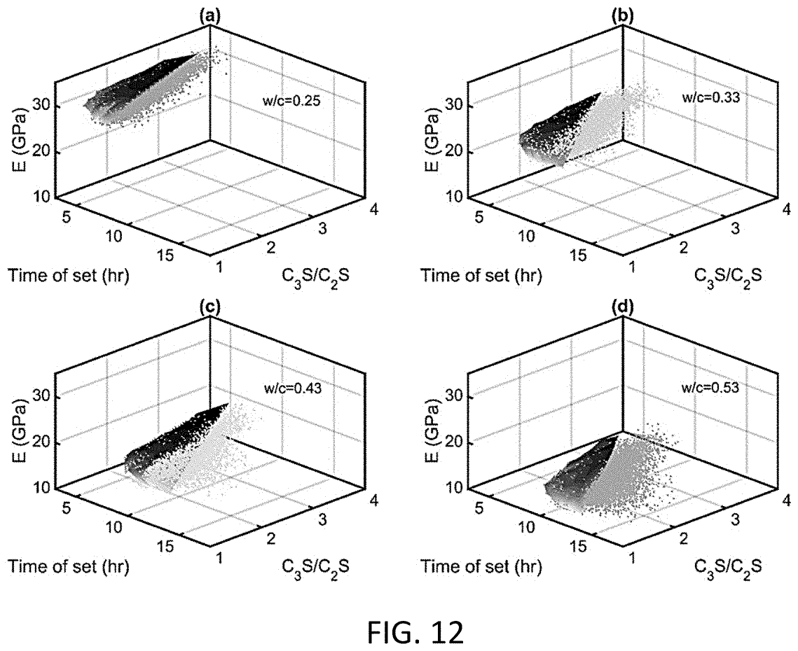

FIGS. 12A-12D show the Pareto fronts for different water to cement ratios when minimizing time of set, minimizing kiln temperature proxy, and maximizing 7-day elastic modulus. Separating the dataset by w/c enables visualization of the variation in the data due to different cement chemistries. The changing slopes of the Pareto surfaces as w/c increases show an increasing sensitivity of modulus and time of set to variations in cement variation. The possible range of moduli at a w/c of 0.53 is larger than that at a w/c of 0.25. C₃S/C₂S is not affected by water-cement ratio because C₃S, C₂S and water-cement ratio are all inputs of cement and independent from one another. The different Pareto fronts provide the non-dominated solutions for different water-cement ratios which could be used as guidance for design. Taking the optimization results with a specified water-cement ratio (0.25) as an example, there are 88 non-dominated solutions found by the PSO algorithm. Table 8 lists the inputs and outputs of the first 30 non-dominated solutions. These solutions provide useful guidance for cement designers. From all trade-off optimal solutions, the selection of inputs for cement design is based on the specifications for cement paste performance.

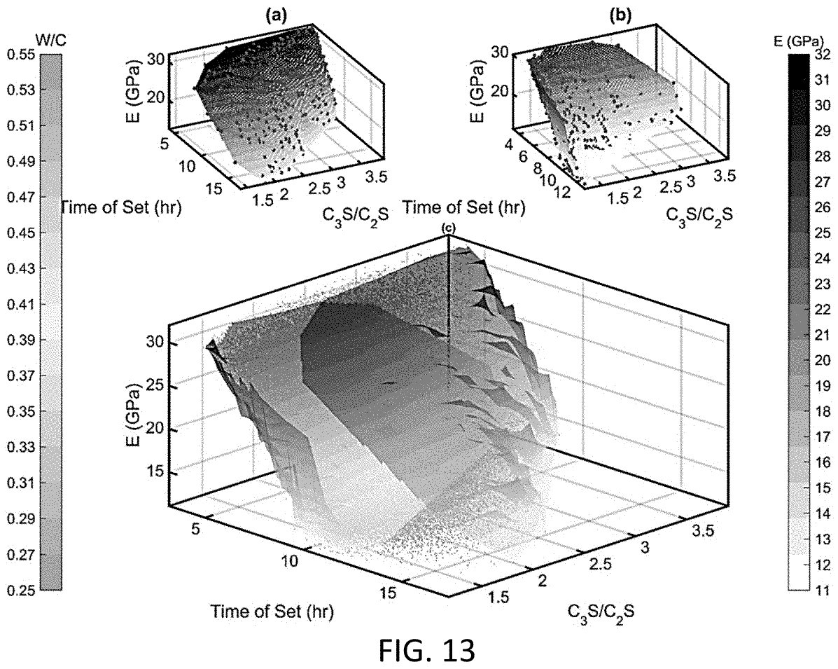

FIG. 13A shows a 3-D surface mesh of Pareto fronts from non-dominated solution (red dots) for the Max-Max-Max case. FIG. 13B shows a 3-D surface mesh of Pareto fronts from non-dominated solution (red dots) for the Min-Min-Min case. FIG. 13C shows the 3-D surface of Pareto fronts for the combined cases. Table 8 lists the inputs and outputs of the first 30 non-dominated solutions. These solutions provide useful guidance for cement designers. From all trade-off optimal solutions, the selection of inputs for cement design is based on the requirements for cement paste performance.

TABLE 8
First 30 non-dominated solutions for min-min-max case (w/c = 0.25)

| | | | | | | | Outputs: Mechanical and | | | |
|---|---|---|---|---|---|---|---|---|---|---|
| | | | | | | | Hydration Properties | | | |
| | | | | | | | | | | 7-day |
| | | | | | | | 7-day | Time | Degree of | Elastic |
| Inputs: Mass Fraction | | | | | | | Heat | of Set | hydration | Modulus |
| Alite | Belite | Ferrite | Aluminate | Gypsum | Anhydrite | Hemihydrate | (kJ/kg) | (hours) | (%) | (GPa) |
| 0.54 | 0.27 | 0.07 | 0.07 | 0.01 | 0.03 | 0.00 | 264 | 4.55 | 0.03 | 31.1 |
| 0.69 | 0.17 | 0.06 | 0.05 | 0.01 | 0.01 | 0.01 | 288 | 4.39 | 0.03 | 32.0 |
| 0.57 | 0.19 | 0.07 | 0.09 | 0.00 | 0.04 | 0.04 | 275 | 3.30 | 0.04 | 30.7 |
| 0.51 | 0.24 | 0.08 | 0.09 | 0.02 | 0.04 | 0.02 | 257 | 3.60 | 0.04 | 29.8 |
| 0.61 | 0.15 | 0.06 | 0.10 | 0.00 | 0.04 | 0.03 | 285 | 3.16 | 0.03 | 31.4 |
| 0.50 | 0.28 | 0.07 | 0.09 | 0.01 | 0.03 | 0.01 | 248 | 4.55 | 0.03 | 29.9 |
| 0.65 | 0.19 | 0.05 | 0.06 | 0.00 | 0.03 | 0.01 | 275 | 3.60 | 0.03 | 31.1 |
| 0.53 | 0.24 | 0.07 | 0.09 | 0.01 | 0.03 | 0.03 | 262 | 3.45 | 0.03 | 30.4 |
| 0.52 | 0.26 | 0.07 | 0.10 | 0.02 | 0.03 | 0.01 | 269 | 4.55 | 0.03 | 30.7 |
| 0.50 | 0.30 | 0.10 | 0.05 | 0.01 | 0.03 | 0.00 | 242 | 4.90 | 0.03 | 29.8 |
| 0.54 | 0.28 | 0.05 | 0.09 | 0.00 | 0.03 | 0.01 | 271 | 4.90 | 0.03 | 31.0 |
| 0.61 | 0.16 | 0.11 | 0.07 | 0.00 | 0.03 | 0.01 | 280 | 3.90 | 0.03 | 31.8 |
| 0.59 | 0.21 | 0.11 | 0.05 | 0.00 | 0.02 | 0.02 | 267 | 4.39 | 0.03 | 31.3 |
| 0.58 | 0.19 | 0.11 | 0.08 | 0.00 | 0.03 | 0.00 | 277 | 4.90 | 0.03 | 31.8 |
| 0.65 | 0.20 | 0.07 | 0.04 | 0.00 | 0.02 | 0.02 | 274 | 4.22 | 0.03 | 31.7 |
| 0.60 | 0.20 | 0.12 | 0.04 | 0.00 | 0.03 | 0.00 | 268 | 4.39 | 0.03 | 31.4 |
| 0.52 | 0.29 | 0.07 | 0.08 | 0.00 | 0.03 | 0.01 | 259 | 4.90 | 0.03 | 30.8 |
| 0.52 | 0.18 | 0.14 | 0.10 | 0.00 | 0.03 | 0.02 | 273 | 4.06 | 0.04 | 30.9 |
| 0.52 | 0.29 | 0.10 | 0.05 | 0.00 | 0.03 | 0.01 | 249 | 4.72 | 0.03 | 30.5 |
| 0.53 | 0.27 | 0.09 | 0.06 | 0.00 | 0.03 | 0.01 | 252 | 4.39 | 0.03 | 30.7 |
| 0.54 | 0.27 | 0.07 | 0.07 | 0.01 | 0.03 | 0.00 | 264 | 4.55 | 0.03 | 31.1 |
| 0.69 | 0.17 | 0.06 | 0.05 | 0.01 | 0.01 | 0.01 | 288 | 4.39 | 0.03 | 32.0 |
| 0.57 | 0.19 | 0.07 | 0.09 | 0.00 | 0.04 | 0.04 | 275 | 3.30 | 0.04 | 30.7 |
| 0.51 | 0.24 | 0.08 | 0.09 | 0.02 | 0.04 | 0.02 | 257 | 3.60 | 0.04 | 29.8 |
| 0.61 | 0.15 | 0.06 | 0.10 | 0.00 | 0.04 | 0.03 | 285 | 3.16 | 0.03 | 31.4 |
| 0.50 | 0.28 | 0.07 | 0.09 | 0.01 | 0.03 | 0.01 | 248 | 4.55 | 0.03 | 29.9 |
| 0.65 | 0.19 | 0.05 | 0.06 | 0.00 | 0.03 | 0.01 | 275 | 3.60 | 0.03 | 31.1 |
| 0.53 | 0.24 | 0.07 | 0.09 | 0.01 | 0.03 | 0.03 | 262 | 3.45 | 0.03 | 30.4 |
| 0.52 | 0.26 | 0.07 | 0.10 | 0.02 | 0.03 | 0.01 | 269 | 4.55 | 0.03 | 30.7 |
| 0.50 | 0.30 | 0.10 | 0.05 | 0.01 | 0.03 | 0.00 | 242 | 4.90 | 0.03 | 29.8 |

### REMARKS ON CONVERGENCE

To minimize the computational expense, metaheuristic search algorithms can be terminated once the estimated value is close to the target value. Thus, investigating the convergence properties of the multi-objective evolutionary algorithms is preferred. In the past few years, efficient stopping criteria for MOOP algorithms have been explored. Convergence to the global Pareto front has been considered to assess the performance of the algorithm.

In the cases where problems do not have an exact solution, a true Pareto front cannot be established. Therefore, a convergence test is applied based on the self-improvement of the algorithm. A metric tracking the change of the archive based on non-domination criterion was proposed to generate the convergence curve for MOOP. Two terms were suggested: the improvement-ratio and consolidation ratio. The improvement-ratio represents the improvement in the solution set while the consolidation-ratio represents the proportion of potentially converged solutions. The algorithm is considered to converge when improvement-ratio is close to zero and the consolidation-ratio is close to one. This method was applied to the Min-Min-Min case above to test the convergence for the PSO algorithm with different population sizes. Consolidation-ratio and improvement ratio are calculated for each generation to create the convergence shown in Table 9.

TABLE 9
Convergence test results for 149,572 simulations

| | | Number of | | |
|---|---|---|---|---|
| | Number of | Non- | Number of | Number of |
| Population | Convergence | Dominated | PSO | Simulations |
| Size | Generation | Solutions | Simulations | PSO/VCCTL |
| 10 | 2,200 | 66 | 19,812 | 13.2% |
| 20 | 1,500 | 71 | 26,006 | 17.4% |
| 30 | 1,400 | 85 | 35,189 | 23.5% |
| 40 | 1,300 | 81 | 42,866 | 28.7% |
| 50 | 1,000 | 82 | 42,416 | 28.4% |
| 100 | 900 | 90 | 61,907 | 41.3% |
| 200 | 800 | 88 | 98,181 | 65.6% |
| 300 | 600 | 88 | 104,762 | 70.0% |
| 500 | 400 | 88 | 110,317 | 73.8% |

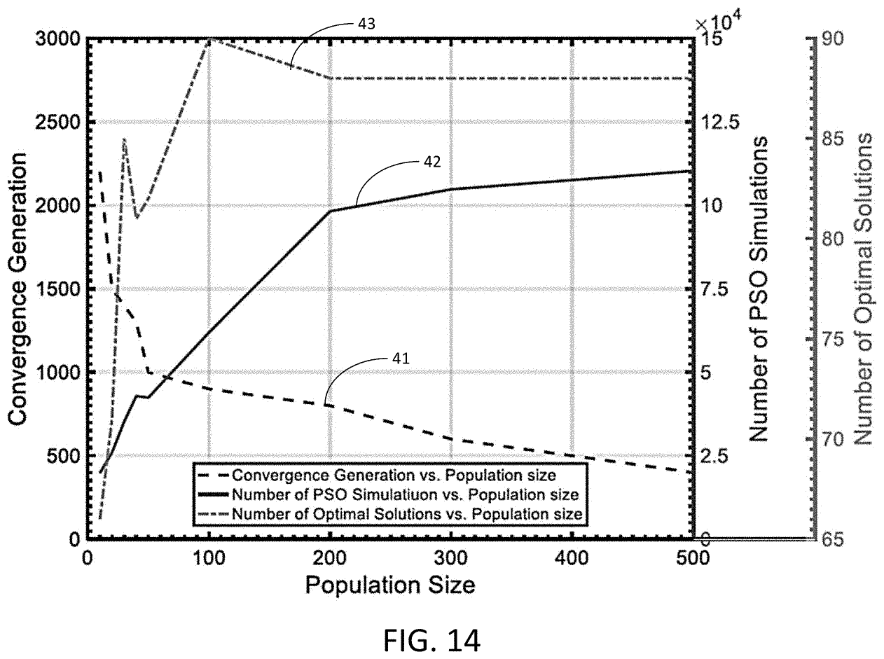

Table 9 lists the number of convergence generations and population sizes. After the PSO algorithm is applied, the computational cost is reduced by approximately 90% compared with the original cost. The relation between population size, convergence generation and number of PSO simulations is plotted in FIG. 14, which shows plots of convergence generation vs. population size 41, number of PSO simulations vs. population size 42, and number of optimal solutions vs. population size 43. FIG. 14 shows that, with increasing population size, the number of generations needed for convergence decreases and the number of optimal solutions increases. This trend means a larger population size results in faster convergence. Also, the minimum number of simulations with PSO is about 19,812 out of 149,572 VCCTL simulations, which means the algorithm drastically decreases the computational cost in the process of searching optimal solutions for cement.

### Potential for Objective Rating of Cement Quality

The present disclosure will now describe how Pareto front analysis can be applied to quantify the performance of a single cement relative to other cements, with user specified constraints such as imposing a minimum allowable modulus or maximum allowable time of set. Currently, a numerical rating system to objectively rate cement quality does not exist in practice. Similar to other civil engineering materials such as timber and steel (Standard), Portland cements are stratified into discrete classes based on physical testing results and intended service applications (Cement). A major limitation of this approach in practice is the assumption that all cements of a given class are equivalent in performance. The integration of PSO with cement hydration modeling in accordance with embodiments described herein allows for performance-based scoring on a continuous basis without physical testing, and defines a framework for the practical implementation of performance based specifications that complement existing approaches.

### Cement Scoring System

The proposed scoring system is based on the probability of non-exceedance of the data encompassed by the Pareto fronts given a user-specified constraint such as E≥E0:

P_{c}(dₙ|E≥E₀) Eq. 34

where Pc is the probability of non-exceedance, dₙ is the normalized Pareto front distance, and E₀ is the minimum allowable modulus.

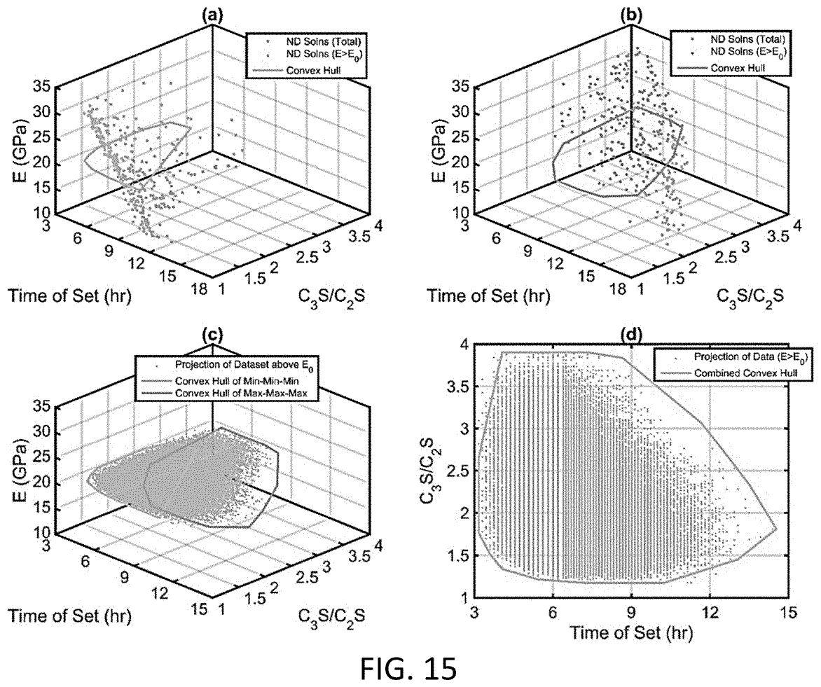

In this case, the Min-Min-Min and Max-Max-Max Pareto fronts give the boundary cases for all modeled cements. These fronts are used to calculate cement scores according to the following procedure:
1. Project cements with E≥E0 to the surface E=E0 (E0=20 GPa).
2. Unite two Pareto fronts (Min-Min-Min and Max-Max-Max) at E=E0 to create a convex hull. FIG. 15 shows the process of finding a convex hull from the Pareto fronts. FIG. 15A shows the process of finding the convex hull for Min (Time of set)−Min (C3S/C2S)−Min (E) case; FIG. 15B shows the process of finding the convex hull for Max (Time of set)−Max (C3S/C2S)−Max (E) case; FIGS. 15C and D and (d) show the combined convex hull. For cement data points close to the Min (Time of set)−Min (C3S/C2S)−Min (E) Pareto front have a higher score and those close to the Max (Time of set)−Max (C3S/C2S)−Max (E) Pareto Front have a lower score. The two Pareto fronts are projected to the surface E=E0 and the convex hull combining the two projected Pareto fronts is applied. The left and bottom side of the convex hull belongs to the min-min-min case (lowest score) while the right and top sides belong to the max-max-max case (highest score). Normalized distances from 0 to 1 are arranged from the min-min-min case to the max-max-max case. For each cement data point, distances to the worst and best boundaries on the convex hull are calculated in two directions.
3. Calculate the normalized distance from the convex hull for each cement in the time of set and heat proxy directions.
4. Evaluate the cumulative distribution function of normalized distances in each direction for the group of cements. The probability of non-exceedance for each direction is used to score each cement
5. Prioritize the two parameter scores with user specified weights, and then combine using equation 35:

$${S}_{comb} = \frac{{w}_{1} \times {s}_{1} + {w}_{2} \times {s}_{2}}{{w}_{1} + {w}_{2}} \qquad Eq . 35$$

where w₁ and s₁ are the weight and score in the time of set direction, while w2 and s2 are the weight and score in the heat proxy direction (w₁+w₂=1).

### Scoring System Applied to Example 3

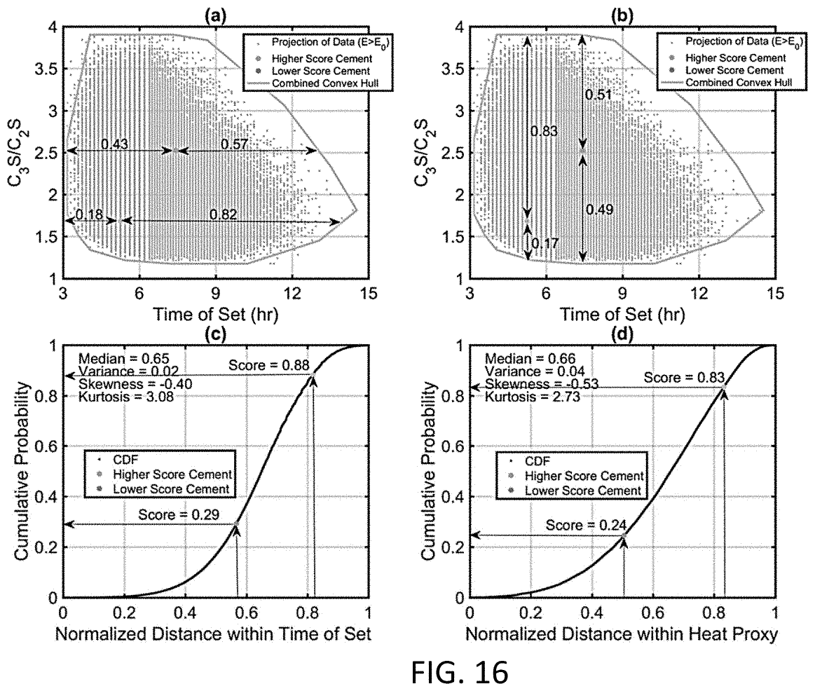

FIG. 16 demonstrates the scoring procedure with two example cements. The score is defined as the probability of non-exceedance for the specified cement relative to all cements that meet the user specified constraints (here the modulus). Scores of zero and unity represent the worst and best possible outcomes, respectively. FIGS. 16A and 16B detail the calculation of the normalized distance from the convex hull in the time of set and heat proxy directions for each cement. FIGS. 15D and 15E illustrate the assignment of a probability of non-exceedance score using the cumulative distribution of the normalized distances based on the scoring in FIGS. 16A and 16B, respectively.

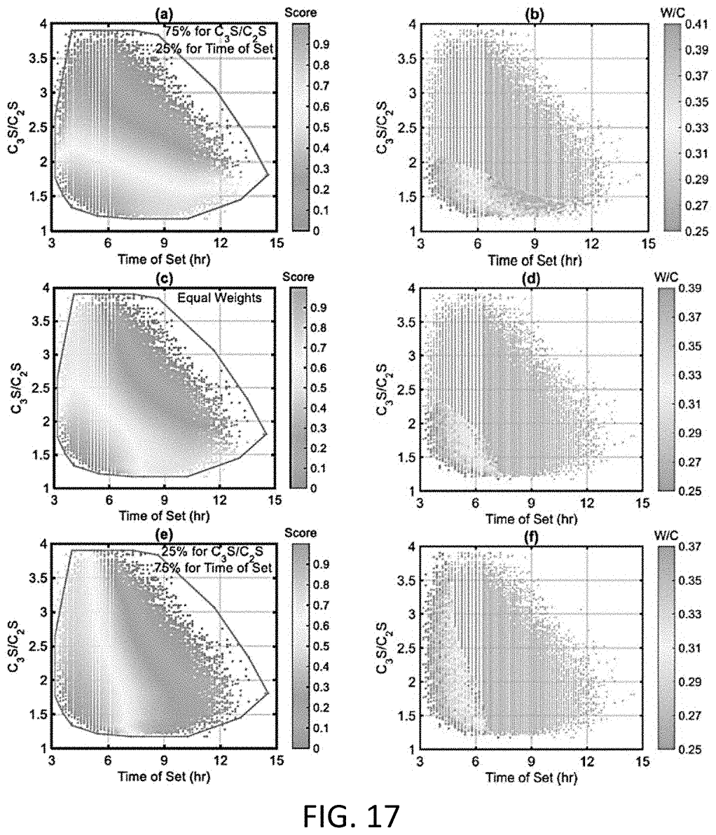

FIG. 17 shows an example case for the application of objective, performance based scoring to cement paste design with respect to user needs for time of set, C₃S/C₂S, and w/c. FIGS. 17A, 17C and 17E show the spectrum of combined scores with 75%, 50%, and 25% weight, respectively, for C₃S/C₂S. In the figure, colorbar purple represents the lowest score and dark green represents the highest score. This provides a visual map of the ideal cases based on the relative priority of the two scored parameters, where all cases satisfy the constraint E>20 GPa. Specification of a minimum combined score, e.g. 0.7, demonstrates the behavior variation of cases exceeding that score as the weights change. Cases with combined scores exceeding 0.7 have longer setting times with a higher heat proxy weight and larger heat proxy values with higher setting time weight.

FIGS. 17B, 17D and 17F show the portion of the dataset with a score exceeding 0.7 for each set of weights; the colorbar indicates the water to cement ratio, with red representing the lowest w/c, and blue representing the highest w/c. A lower w/c typically leads to better performance in Portland cement based materials. However, this is limited by the need for adequate workability. The ideal case in this example has the largest w/c, to maximize workability while exceeding the minimum combined score and meeting the constraint E≥E0. The maximum w/c decreases from 0.41 to 0.37 as the combined score weights shift in favor of time of set, and for all three weights the majority of cases have water to cement ratios that are much lower.

### Implication

This following portion of the present disclosure presents the successful application of multi-objective optimization of cement modeling, applied to a cement database created from ˜150,000 VCCTL simulations. Pareto fronts were explored for constrained bi-objective or non-constrained tri-objective problems. Compared to full enumeration of the VCCTL parameter space, the metaheuristic algorithm search decreases the cost by nearly 90%. This finding suggests that this approach may be promising for evaluating much larger input variable sets.

The Portland cement industry is moving toward the implementation and use of performance specifications. It is often the case that to ensure durability, cement and concrete producers specify concrete mixtures to be stronger than needed, even when overdesign is specified, due to perceived uncertainty regarding the ultimate performance of the material. To alleviate this, performance based design should address the needs of the industry, which include the assurance of strength, durability, economy, and sustainability. Pareto front based scoring of virtual testing results allows for the rapid assessment of solutions through constraints on parameters, while providing relative performance values for secondary parameters of interest. This enables immediate visualization of possibilities, and rapid selection of ideal cases.

Objective, performance based scoring has the potential to improve the economic performance of ordinary Portland cement (OPC) systems without the need of supplementary materials. Modem Type I/II Portland cements are empirically optimized for fast construction and low cost. Current cement compositions use supplementary materials to improve longevity and increase sustainability. Quantification of the tradeoffs between rapid strength development, cost of production, and long-term durability for Portland cement could motivate changes to cement chemistry and lead to optimization of the production process.

As introduced, numerical models can exist to understand the behaviors of cement kilns, increase the cement production and decrease the energy consumption and greenhouse gas emissions. To simulate reactions of the rotary kiln and optimize the process and outputs, the following describes a physical-chemical one-dimensional kiln model developed based on knowledge of thermodynamics and clinker chemistry from existing models. MATLAB R2016a™ solver ODE15s is used to solve the ordinary partial differential equation system of the kiln model. The temperature profiles and clinker species mass fractions are validated with existing industrial kiln model and Bogue calculation.

Although measuring data from operation cement plants is available at times, it is subject to confidentiality and inherent limitations. The cement plant data such as clinker production, energy cost, and CO₂ emission is restricted to the precise operating parameters that occurred at that time. Also, the majority of these parameters can only be estimated within a certain degree of accuracy. For these reasons, research on the continued understanding of cement rotary kiln is slow and heavily focused on computational modeling.

### Solution Methodology

According to previous kiln models developed during last 50 years, knowledge inside the model is similar, including the thermodynamics and clinker chemistry. However, the approaches researchers used to solve the model are quite different. Some people developed their own code with numerical methods (usually the fourth-order Runge-Kutta method) to solve for the ODE/PDEs, while others used commercial software or open source numerical solves for their models.

For current study, the kiln model Equations 1-30 are implanted into Matlab2016a™ and the solver ODE15s is applied to solve the ODE system because of its high computational efficiency and convenience in coupling with the optimization tool described above. By testing different ODE solves including ODE45, ODE23, ODE15s, ODE23s, ODE23t, ODE23tb in Matlab2016, ODE15s is more stable and performs better than other solvers in solving stiff differential equations and dealing with singular matrix.

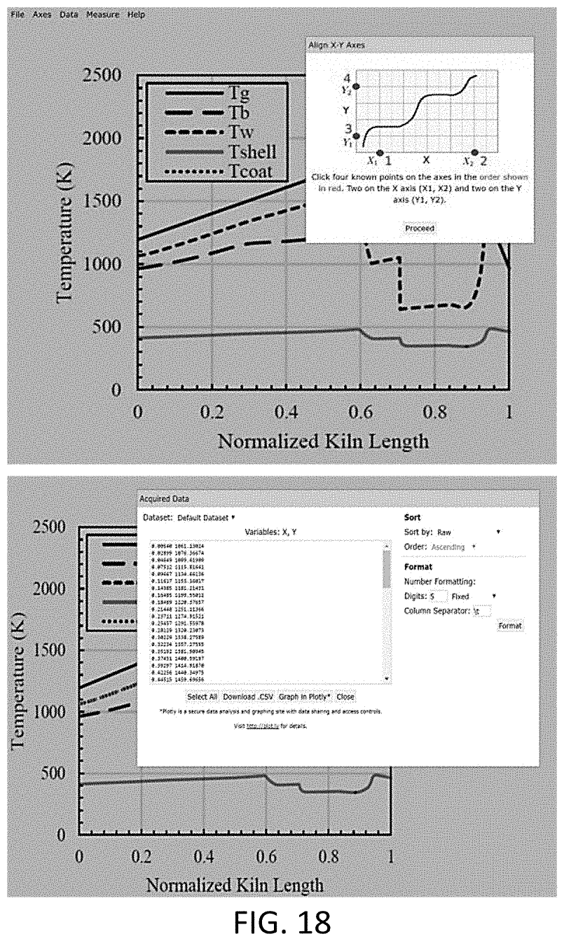

The procedure to solve for the computational kiln model is as follows:
1. An assumed temperature profile for the bed, gas, and shell was generated by assuming what the temperatures may be throughout the kiln based on results from other researchers. A linear profile for the gas temperature is generated in order to simplify the model. This profile was generated using the inlet and outlet gas temperature, as well as an assumption for the temperature and location of the peak gas temperature based on data received from the partner plant. The initial temperature profile was obtained by using a tool called “Plot Digitizer” to digitize the plots from papers. This tool allows one to pick the axis of a graph and choose the points on the plot, and then it generates a table of the x and y values (shown in FIG. 18)
2. Internal heat transfer components were solved from Equations 1 to 10 excluding the effects of clinker chemistry.
3. ODE system equations 16-29 were solved for bed temperature and species mass fractions through the use of Matlab2016a ODE15s solver. The bed temperature specified for each chemical reaction shown in Table 2 is taken into consideration.
4. Shell temperature was solved using the heat balance Equation 30 by Newton-Raphson method.
5. A check was performed to see if the new temperature profiles of shell and solid bed were within residual of 0.000001 of the previous profile.
6. The new temperature profiles were passed back to the beginning of the model (step 2) and the process repeated again till convergence.

### Results and Discussion

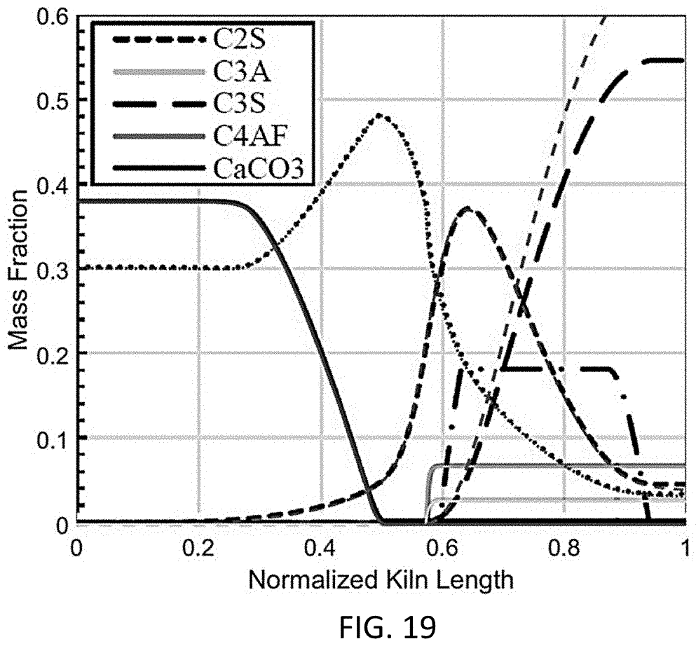

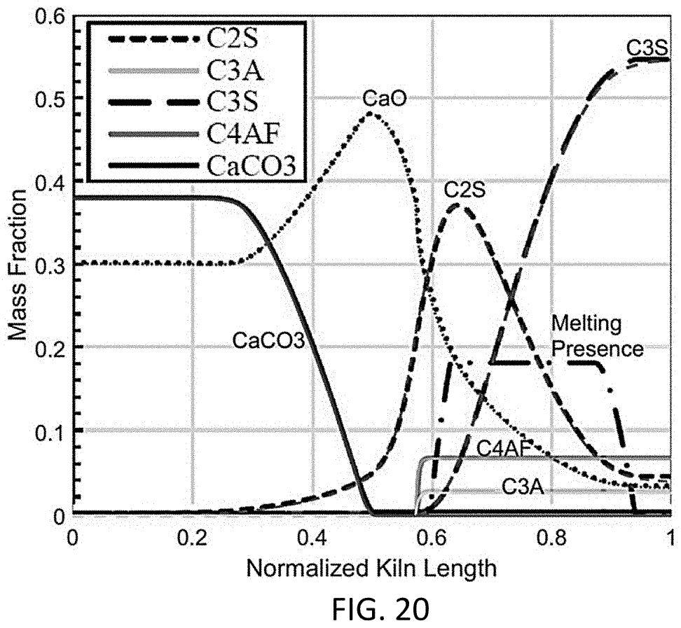

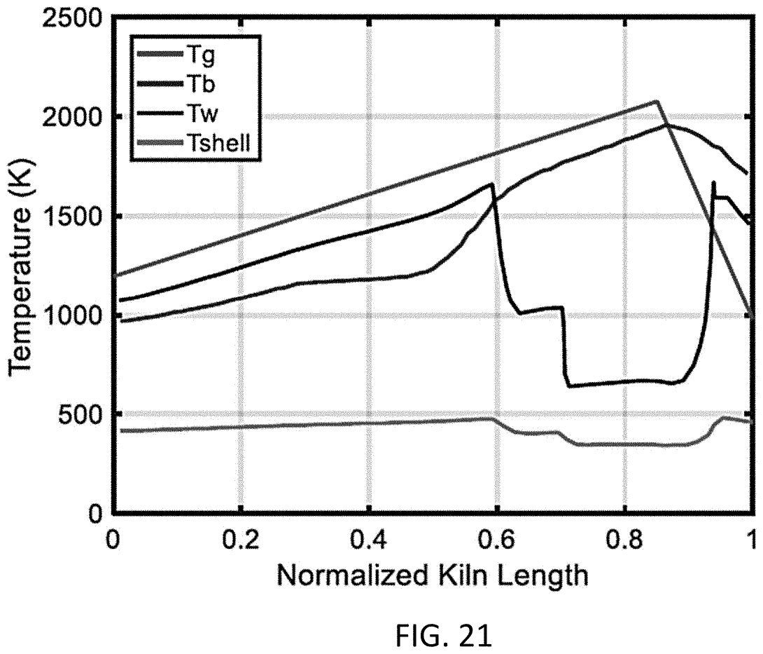

From the solution methodology described above, the 1-D physical-chemical kiln model was solved after the iterative process converged to a solution for solid bed temperature and shell temperature, and mass fraction was plotted. Bed height was taken as an adjustable factor for C₃S at the exit of kiln. FIG. 19 shows species mass fraction along the axial length of cement kiln without adjusting bed height, which generates 20% more C₃S compared with a previous result. FIG. 20 shows the species mass fractions along the cement kiln after adjusting the bed height from 0.75 m to 0.58 m. The mass fraction for each species matches well with previous results. FIG. 21 shows the temperature profiles of solid bed, shell, internal wall and freeboard gas along the kiln, which also matches well with previous results.

Table 10 shows the comparison of inlet and outlet mass fraction of material compared to the calculation and prediction results. From the clinker mass fraction at the outlet of kiln, present prediction is close to the prediction (1.24% difference), while has 15.89% difference compared to the calculation. The reason for the difference is the calculation assumes entire amount input constituent are converted into their species, which causes inherent error.

TABLE 10
Species mass fractions model predictions compared
with Bogue and Csernyei's prediction

| | Mass Fraction | |
|---|---|---|
| Raw Meal at | from Csernyei's | Mass Fraction of |
| inlet | Work | Present Work |
| CaCO₃ | 0.3798 | 0.3798 |
| CaO | 0.3019 | 0.3019 |
| SiO₂ | 0.1594 | 0.1594 |
| Al₂O₃ | 0.0246 | 0.0246 |
| Fe₂O₃ | 0.0396 | 0.0396 |
| Inert + Other | 0.0947 | 0.0947 |

| | Mass Fraction | Mass Fraction | |
|---|---|---|---|
| Clinker at the | from Bogue's | from Csernyei's | Mass Fraction of |
| Outlet | Calculation | Work | present work |
| C₃S | 0.582 | 0.546 | 0.546 |
| C₂S | 0.130 | 0.049 | 0.041 |
| C₃A | 0.063 | 0.027 | 0.027 |
| C₄AF | 0.075 | 0.068 | 0.068 |
| CaO | 0.000 | 0.034 | 0.033 |
| Summation | 0.85 | 0.724 | 0.715 |

After comparison with the calculation and prediction, the present model was verified with more published industrial data as well as some other researcher's prediction. Table 11 shows the comparison between prediction of present work with three cement plant data and another prediction. From the outlet mass fraction, prediction of present work matches with published plant data very well.

TABLE 11
Model predictions compared with industrial data and Mujumdar’s prediction

| Industrial kiln 1 (2006) | | | Industrial kiln 2 (2006) | | | Industrial kiln 3 (2006) | | |
|---|---|---|---|---|---|---|---|---|
| Plant | Mujumdar's | Present | Plant | Mujumdar's | Present | Plant | Mujumdar's | Present |
| Data | Prediction | Work | Data | Prediction | Work | Data | Prediction | Work |

Inlet Mass Fraction

| | | | |
|---|---|---|---|
| CaCO₃ | 0.340 | 0.398 | 0.305 |
| CaO | 0.396 | 0.335 | 0.418 |
| SiO₂ | 0.179 | 0.185 | 0.190 |
| Al₂O₃ | 0.0425 | 0.041 | 0.043 |
| Fe₂O₃ | 0.0425 | 0.041 | 0.043 |
| Initial | 1123 | 1250 | 1025 |
| Temperature | | | |
| of Solid, K | | | |

Outlet Mass Fraction

| | | | | | | | | | |
|---|---|---|---|---|---|---|---|---|---|
| C₃S | 0.483 | 0.508 | 0.489 | 0.508 | 0.502 | 0.503 | 0.500 | 0.504 | 0.506 |
| C₂S | 0.239 | 0.222 | 0.202 | 0.257 | 0.263 | 0.209 | 0.269 | 0.249 | 0.222 |
| C₃A | 0.051 | 0.051 | 0.048 | 0.048 | 0.051 | 0.048 | 0.042 | 0.052 | 0.048 |
| C₄AF | 0.143 | 0.149 | 0.116 | 0.151 | 0.148 | 0.109 | 0.142 | 0.147 | 0.118 |
| Residual | | | 1.82% | | | 2.38% | | | 2.08% |

### Optimization of Coupled VCP/VCCTL Model

This portion of the present disclosure introduces a coupled model which utilizes the VCP in combination with the VCCTL to create a tool which models the production of Portland cement from the mine to the point of placement. The coupling of VCP and VCCTL was performed to provide a tool that couples cement production and hydration Portland cement. The model is a tool for the optimization of raw material input, fuel, energy, emission and cost for manufacture of Portland cement in addition to the optimization of the physical properties of the resultant concrete.

### Coupling VCP and VCCTL Modeling

### Input Generation

The previous section of the present disclosure introduced a 1-D physical-chemical cement kiln model, which is considered as a virtual cement plant (VCP). In order to simulate the VCP, input files including the mass fraction of raw meal, peak gas temperature and the location where peak gas temperature occurs within the kiln are used.

The chemical composition of the raw meal at the inlet of cement kiln includes CaCO₃, CaO, SiO₂, Al₂O₃, Fe₂O₃. It is common to use lime saturation factor (LSF), silica ratio (SR), and alumina ratio (AR) in chemical analysis for cements, clinkers and phases instead of using oxide components directly. The relationship between LSF, SR, AR and raw meal is as follows:

Lime saturation factor (LSF)=CaO/(2.8SiO₂+1.2Al₂O₃+0.65Fe₂O₃) Eq. 36

Silica ratio (SR)=SiO₂/(Al₂O₃+Fe₂O₃) Eq. 37

Alumina ratio (AR)=Al₂O₃/Fe₂O₃ Eq. 38

LSF is a ratio of CaO to the other three oxide components, which control the ratio of alite:belite produced within the cement kiln. The VCP model uses the mass fraction of raw meal, calculated from Equations 36-38, where the LSR, SR, AR, Fe₂O₃, CaCO₃/CaO are considered as inputs which generate oxide components from the raw meal. The typical range for each ratio for the production of Portland cement can be as follows:

LSF—[0.9, 1.05]

SR—[2.0, 3.0]

AR—[0.8, 2.0]

Furthermore, the typical range of Fe₂O₃ content is [0.01,0.1]. The CaCO₃ to CaO ratio is typically within a range of [40%, 60%] and is directly obtained from the decarbonation of the limestone through the kiln. Ultimately the mass fraction of the components, (CaCO₃, CaO, SiO₂, Al₂O₃, Fe₂O₃) should be equal to 1. The inputs are generated utilizing two methods: a) fixed intervals; and b) uniformly distributed random numbers based on the ranges from each input.

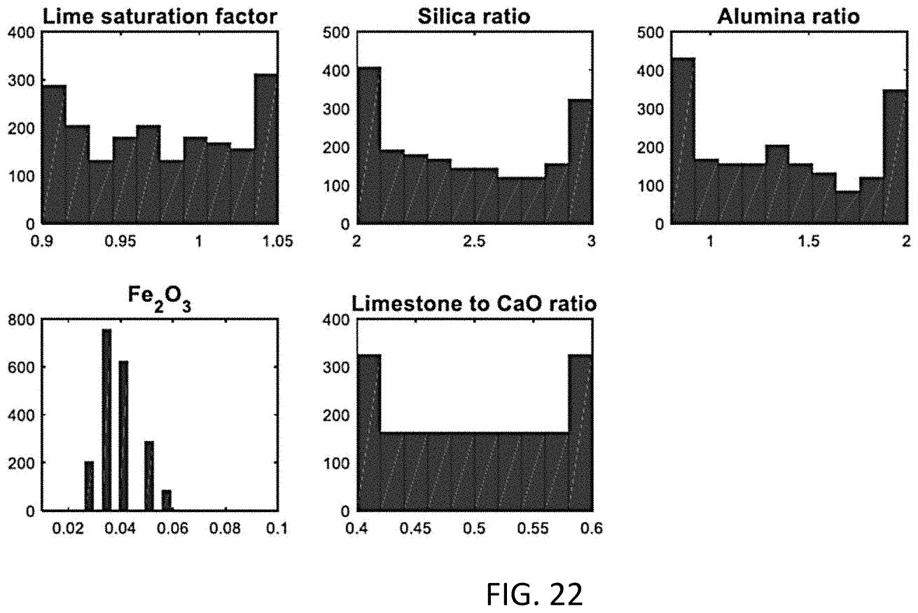

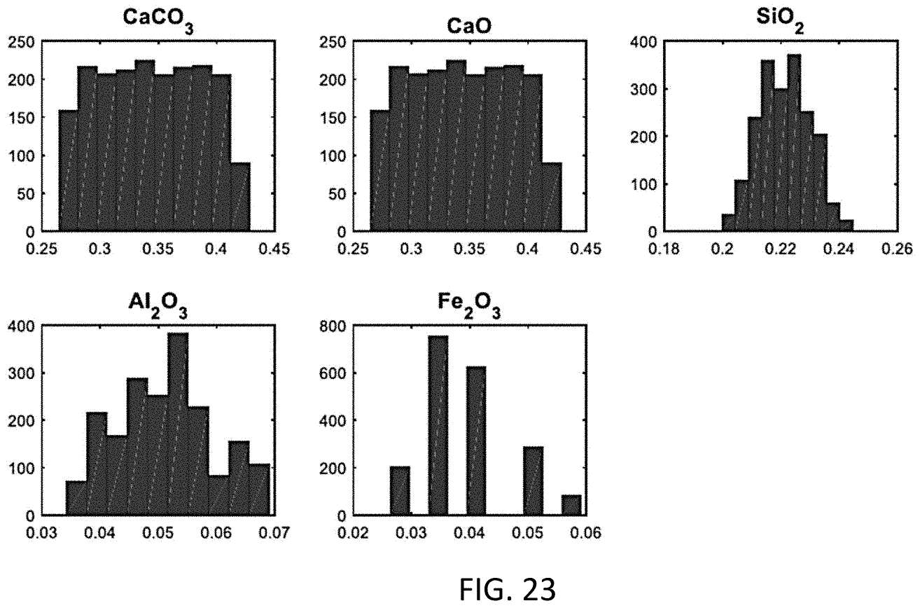

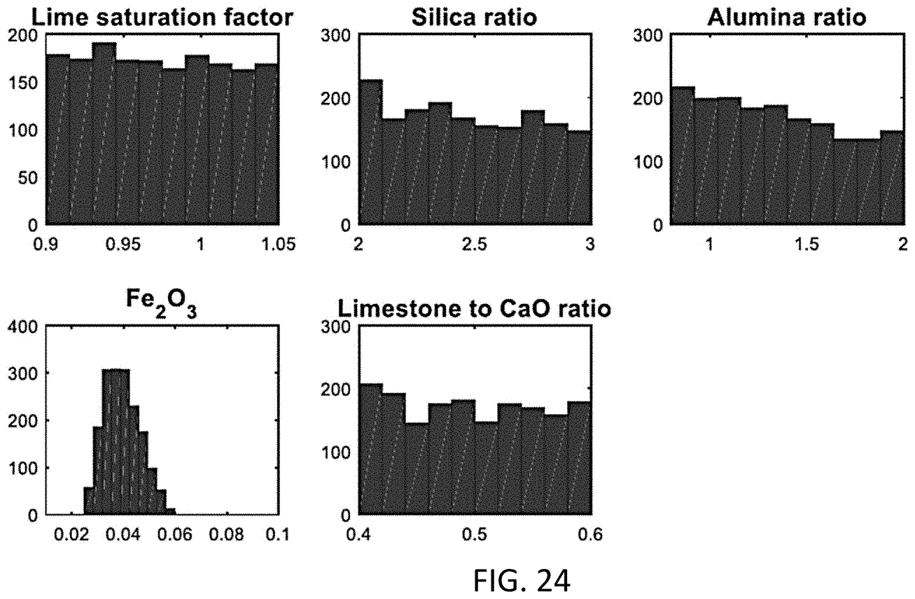

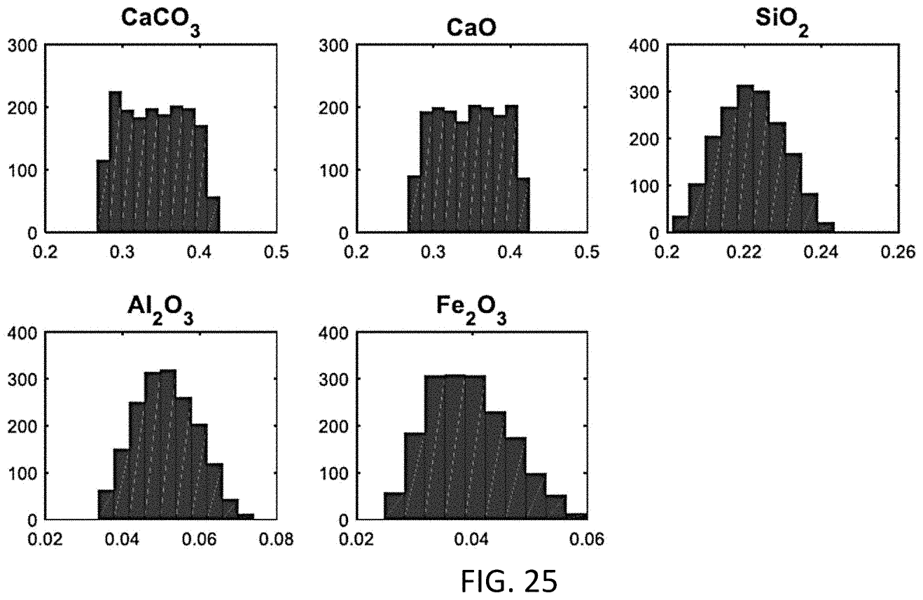

FIGS. 22 and 23 provide the distribution of 1956 inputs generated by fixed intervals, where distributions of raw meal are derived from Equations 36-38. The input was generated from 100,000 individual samples, however, 1956 inputs or 1.96% satisfy the constraint (components equal to 1). FIGS. 24 and 25 show the distribution of inputs generated by uniformly distributed random numbers from the available section and distribution of raw meal. 200,000 individual samples were generated and only 1732 (0.87%) inputs satisfy the constraint. The methodology used for the generation of different sample sizes (100,000 and 200,000) was performed in an effort to acquire roughly the same number of inputs for each case (1956 and 1732). The fixed intervals (method a) did not provide a uniform distribution as shown in FIG. 22; method b, shown in FIG. 23, the uniformly distributed random numbers method was used to generate the inputs for the coupled model.

Table 12 and Table 13 compare the VCP raw meal and clinker mass fraction with different input generation approaches. The results of the two approaches are slightly different, which is to be expected since different methods to generate inputs were used and provides differences in raw meal as well as cement clinker.

TABLE 12
Comparison of VCP raw meal mass fraction from
different input generation approaches

| | Lower Bound | | Upper Bound | | Mean Value | |
|---|---|---|---|---|---|---|
| | Fixed | Uniformly | Fixed | Uniformly | Fixed | Uniformly |
| | Interval | Distributed | Interval | Distributed | Interval | Distributed |
| CaCO₃ | 0.2645 | 0.2666 | 0.4288 | 0.4258 | 0.3440 | 0.3424 |
| CaO | 0.2645 | 0.2665 | 0.4288 | 0.4250 | 0.3440 | 0.3457 |
| SiO₂ | 0.1997 | 0.2014 | 0.2447 | 0.2433 | 0.2211 | 0.2216 |
| Al₂O₃ | 0.0342 | 0.0337 | 0.0691 | 0.0740 | 0.0512 | 0.0512 |
| Fe₂O₃ | 0.0264 | 0.0247 | 0.0591 | 0.0599 | 0.0398 | 0.0394 |

TABLE 13
Comparison of VCP clinker mass fraction from
different input generation approaches

| | From fixed interval inputs | | | From random inputs | | |
|---|---|---|---|---|---|---|
| | Lower | Upper | Mean | Lower | Upper | Mean |
| | bound | bound | Value | bound | bound | Value |
| C₃S | 0.1890 | 0.4822 | 0.2998 | 0.1953 | 0.4574 | 0.3028 |
| C₂S | 0.2330 | 0.3972 | 0.3343 | 0.2445 | 0.3917 | 0.3360 |
| C₃A | 0.0406 | 0.1268 | 0.0797 | 0.0412 | 0.1149 | 0.0725 |
| C₄AF | 0.0691 | 0.1405 | 0.0989 | 0.0712 | 0.1360 | 0.1008 |

It has been reported that the maximum LSF for modern cements is 1.02 and the range for LSF was (0.90-1.05) was borne from the use of a range slightly above the maximum reported. However, the results obtained in Table 13, provide a low range of range of alite (18-48%) but, is typically 40-70%/by mass. Subsequent to the production of the low values for alite, the model was reproduced using the raw meal mass fractions from published industrial kiln data and are applied to determine the range of inputs. After calculating LSF, AR, SR, Fe2O3 and CaCO3/CaO from Equation 36-38 using the mass fractions of raw meal at inlet of the four industrial kilns (shown in Table 10 and Table 11), the ranges for material inputs is as follows: LSF [1.18, 1.36], SR [2.1, 2.5], AR [0.6, 1.0], Fe₂O₃ [0.0396, 0.0430], CaCO₃/CaO [42%, 56%]. Table 14 lists the expanded VCP input ranges combing previous work and information from industrial kilns.

TABLE 14
Expanded VCP material input ranges combing Taylor's ranges and ranges of industrial kilns

| VCP Material | | Range of | Gap Range between Taylor | |
|---|---|---|---|---|
| Input | Taylor's range | Industrial Kilns | and Industrial Kilns | Expanded Range |
| LSF | [0.9, 1.05] | [1.18, 1.36] | [0.09, 1.18] | [0.9, 1.36] |
| SR | [2.0, 3.0] | [2.1, 2.5] | [2.1, 2.5] | [2.0, 3.0] |
| AR | [0.8, 2.0] | [0.6, 1.0] | [0.6, 1.0] | [0.6, 2.0] |
| Fe₂O₃ | [0.01, 0.1] | [0.0396, 0.0430] | [0.0396, 0.0430] | [0.01, 0.1] |
| CaCO₃/CaO | [40%, 60%] | [42%, 56%] | [42%, 56%] | [40%, 60%] |

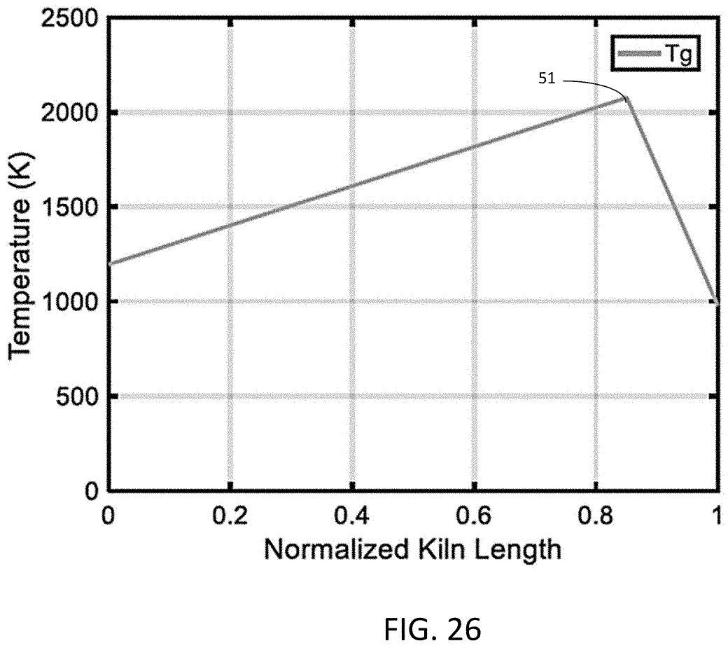

As introduced in the previous section, a gas temperature profile is considered as input for the VCP model, which contains the peak gas temperature and location of the peak gas temperature. FIG. 26 gives an example of gas temperature as an input profile for the VCP. The peak gas temperature of about 2100K happened at the point 51 corresponding to 0.84 of normalized kiln length away from entry of the kiln. Based on other researcher's gas profiles, the peak gas temperature range is chosen as [1976, 2176] K and the range of location of peak gas is chosen as [0.6, 0.9].

### Input Range Testing

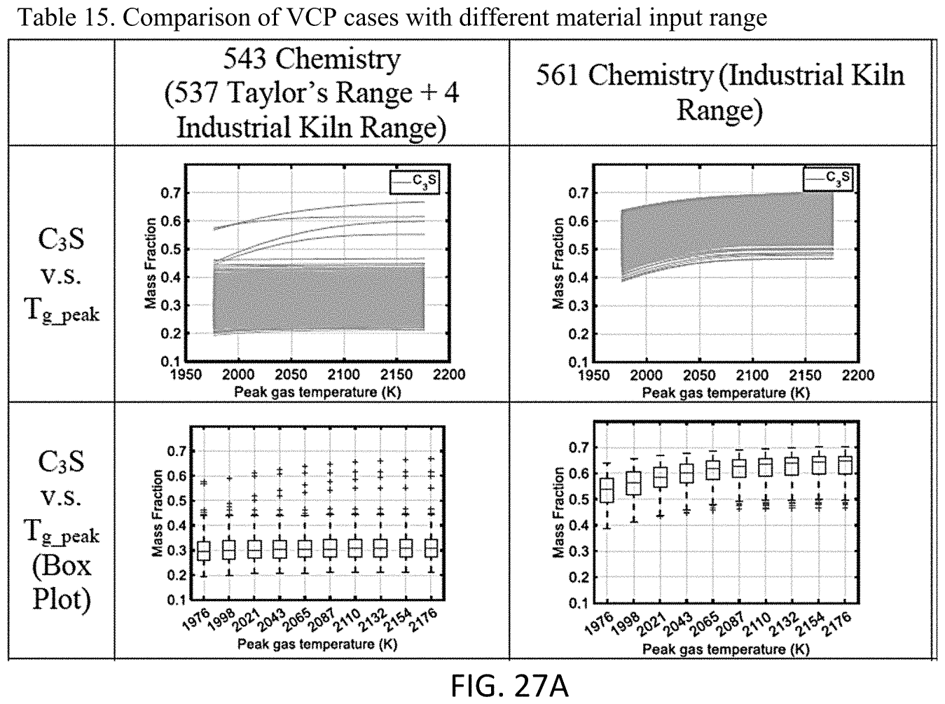

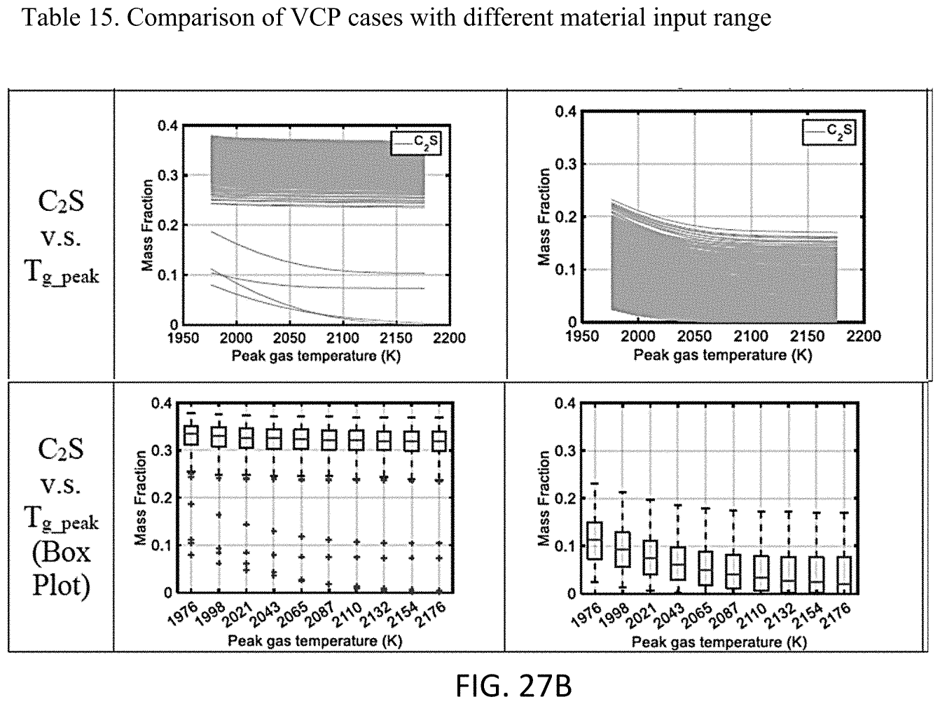

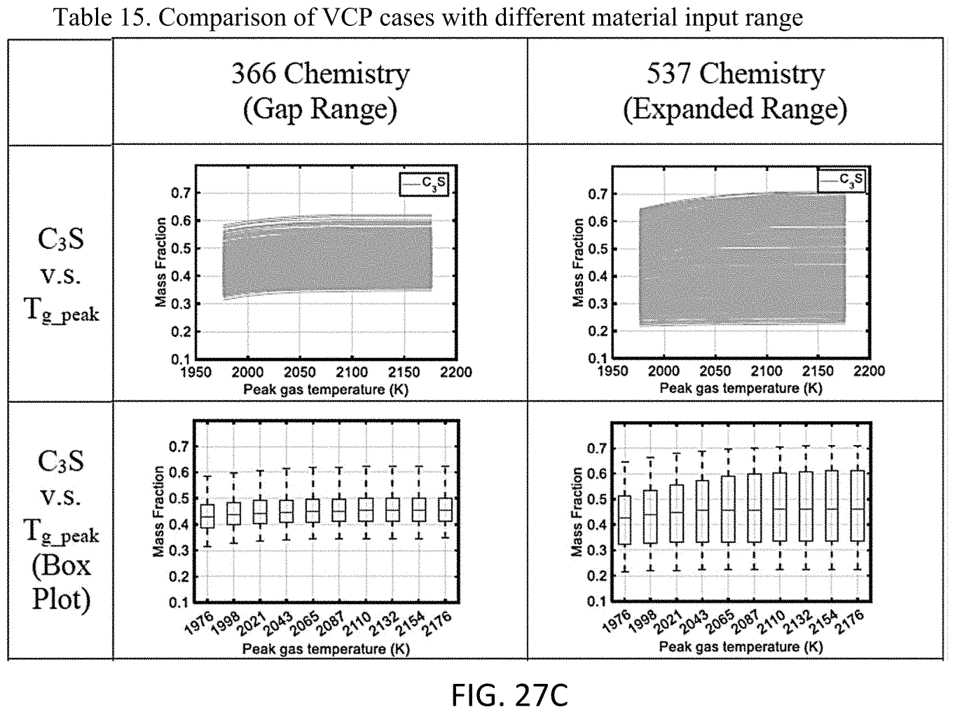

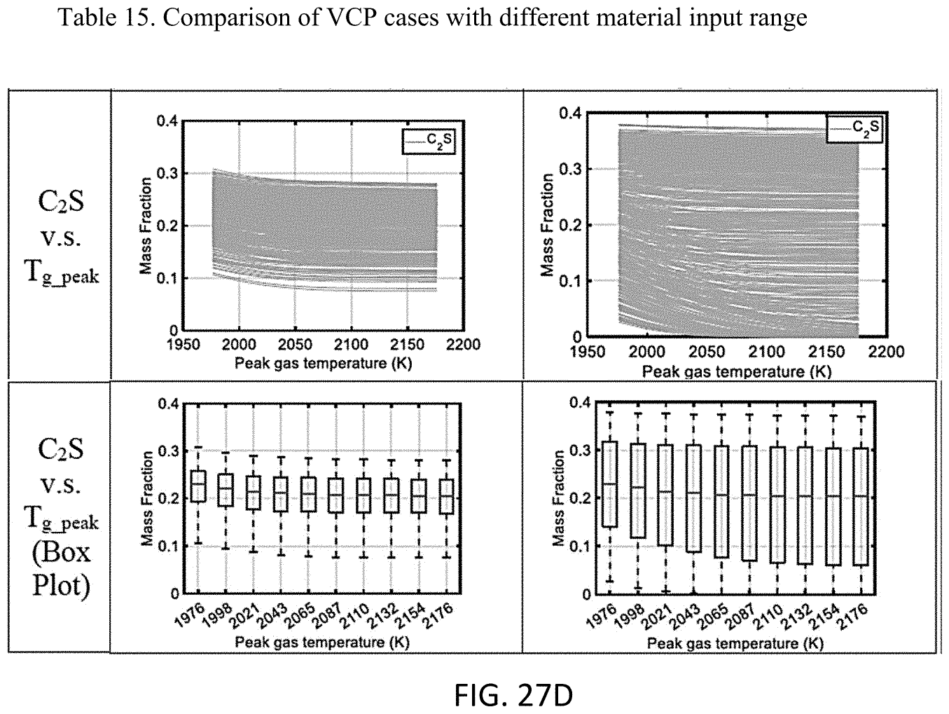

After the ranges for VCP inputs are established, cases with different ranges of material input are analyzed. Table 15 (FIGS. 27A-27D) shows the VCP results with different material input ranges. The results are shown with regards to alite and belite mass fractions at different gas peak temperature. From Table 15 (FIGS. 27A-27D), it can be seen that clinker mass fraction using Taylor's material input range does not cover enough searching space for the optimization tool. After expanding the input range by using information from industrial kilns for VCP, alite space increases from [0.2, 0.45] to [0.2, 0.7] and belite space increases from [0.25, 0.38] to [0, 0.38].

### Schematic of Coupled VCP-VCCTL Model

In the following sections, the expanded inputs including 537 different kinds of chemistry, 10 different peak gas temperatures and 10 different locations of peak gas temperature are considered for coupled VCP/VCCTL model. 53,700 inputs were ported to VCP, after 20 hours running with Matlab2016a, 53,700 clinkers containing the information of mass fractions of virtual clinker phases and related temperature profiles were created. The resultant “virtual clinkers” phase chemistry and fineness are passed to VCCTL and run on UF HPC for virtual cement initial microstructure reconstruction and hydration, as described earlier. Subsequent to 6 days of run-time on the HPC, a series of output indicators with respect to the performance for each virtual cement including time of set, 7-day mortar modulus, 7-day mortar strength, and 3-day heat are calculated.

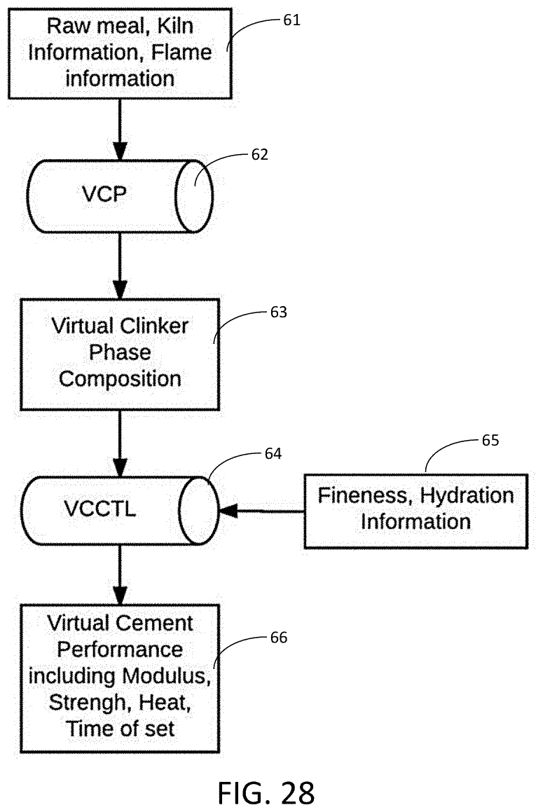

FIG. 28 is a flow diagram of the coupled VCP-VCCTL model algorithm in accordance with a representative embodiment. Blocks 62 and 64 represent the VCP and the VCCTL models, respectively, integrated together. Block 61 represents the inputs that are ported to the VCP 62. Block 63 represents the resultant virtual clinkers phase chemistry that are passed by the VCP 62 to the VCCTL 64. Block 65 represents the fineness and hydration information that are input to the VCCTL 64. Block 66 represents the series of output indicators with respect to the performance for each virtual cement that are generated by the VCCTL 64, such as, for example, time of set, 7-day mortar modulus, 7-day mortar strength, and 3-day heat.

### Case Studies

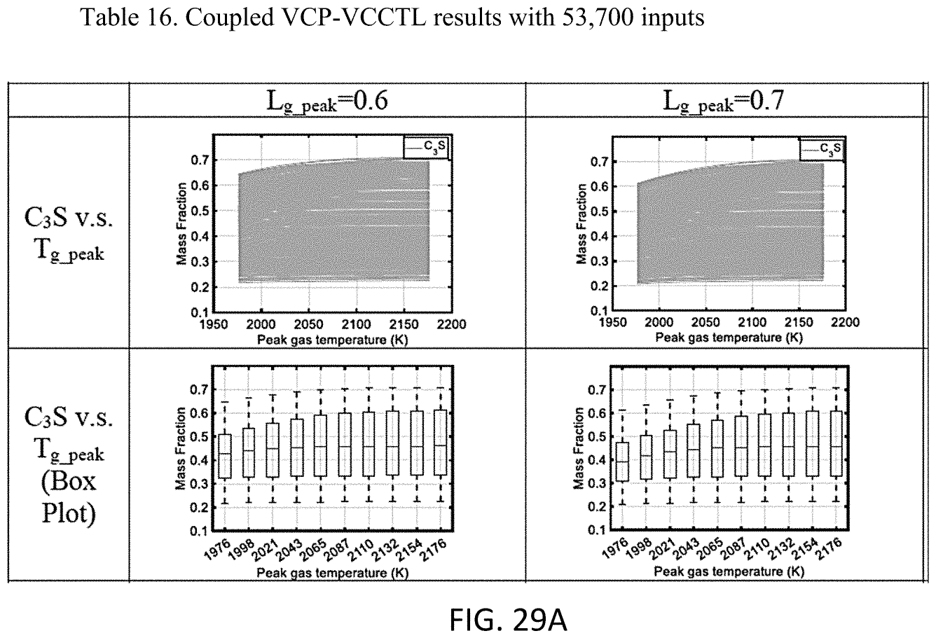

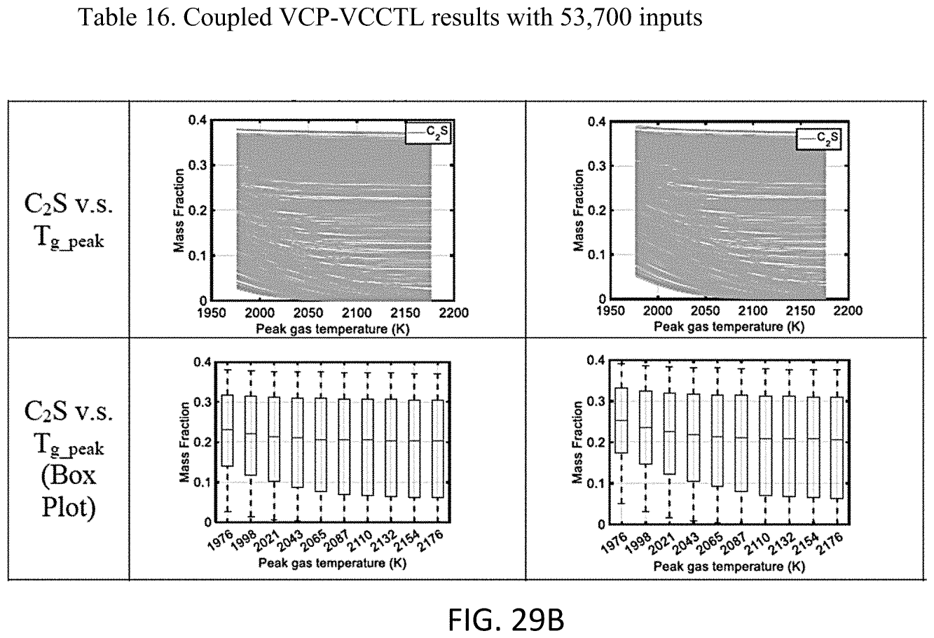

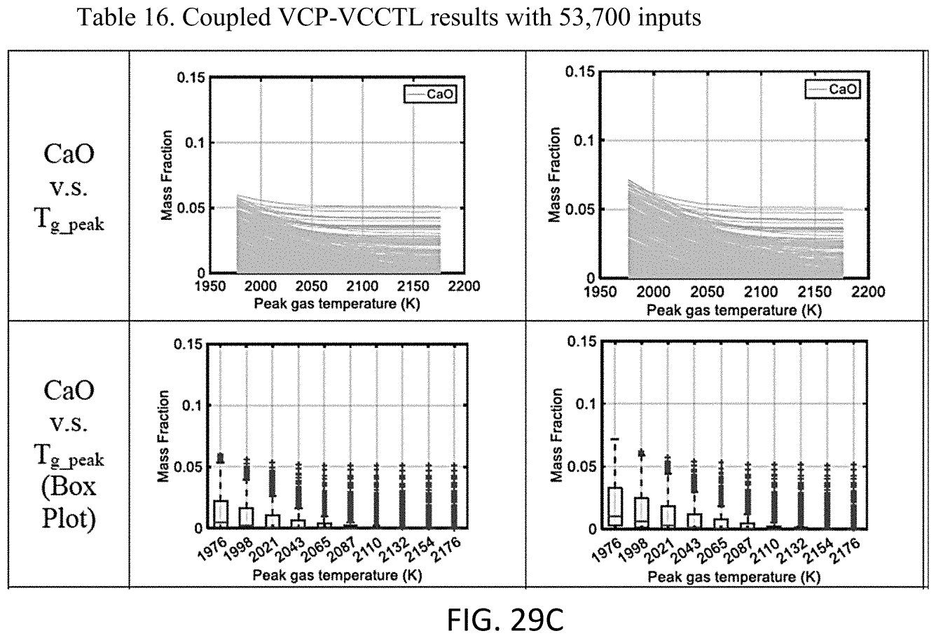

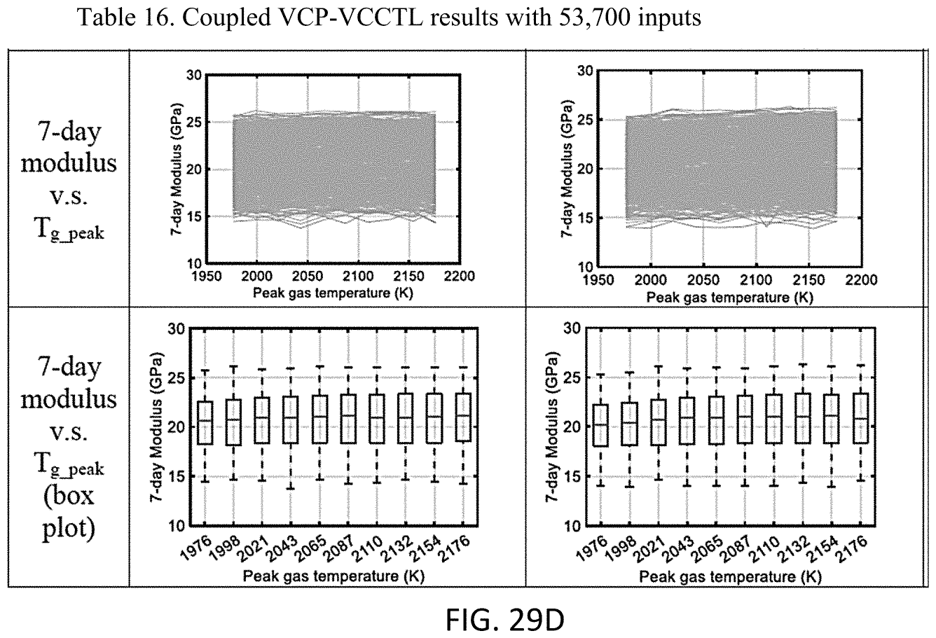

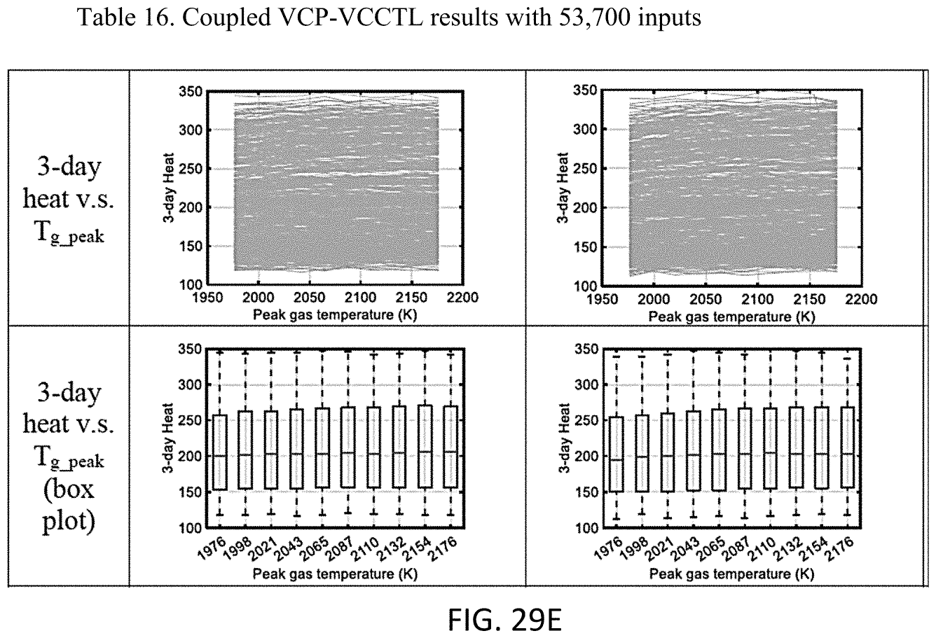

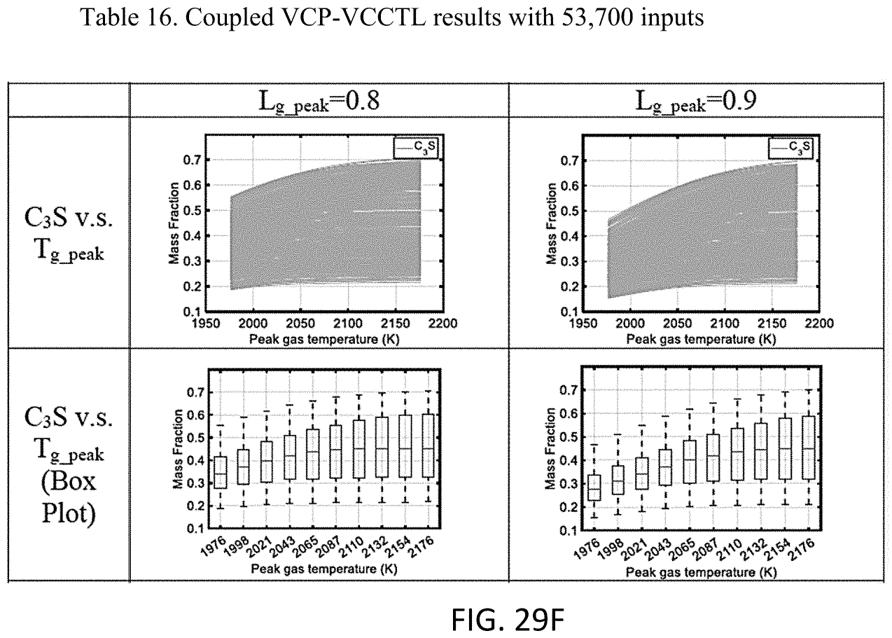

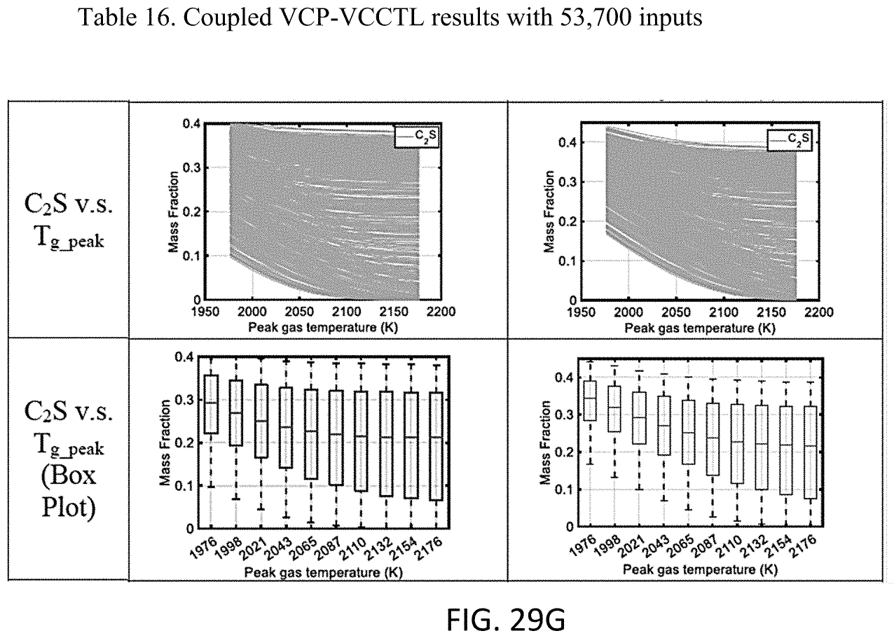

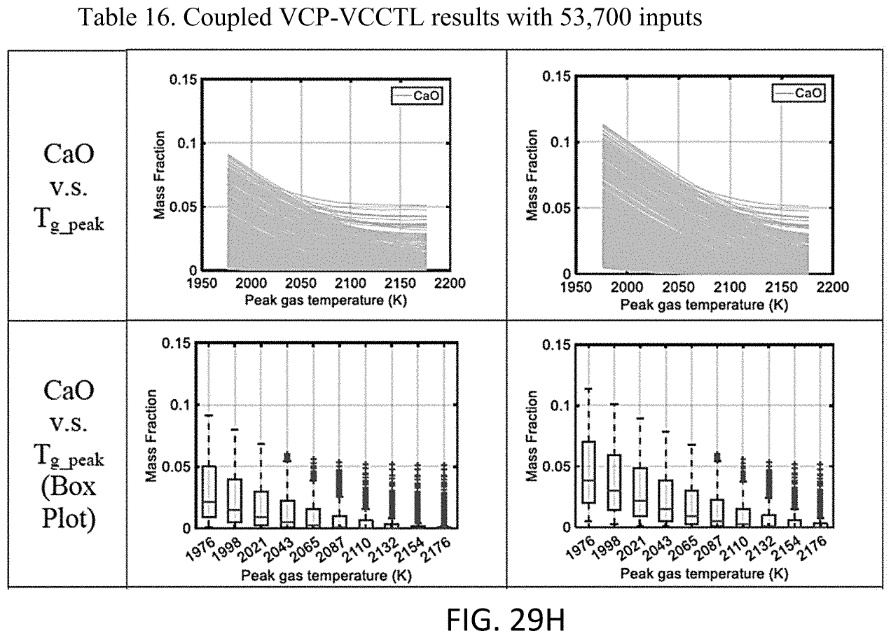

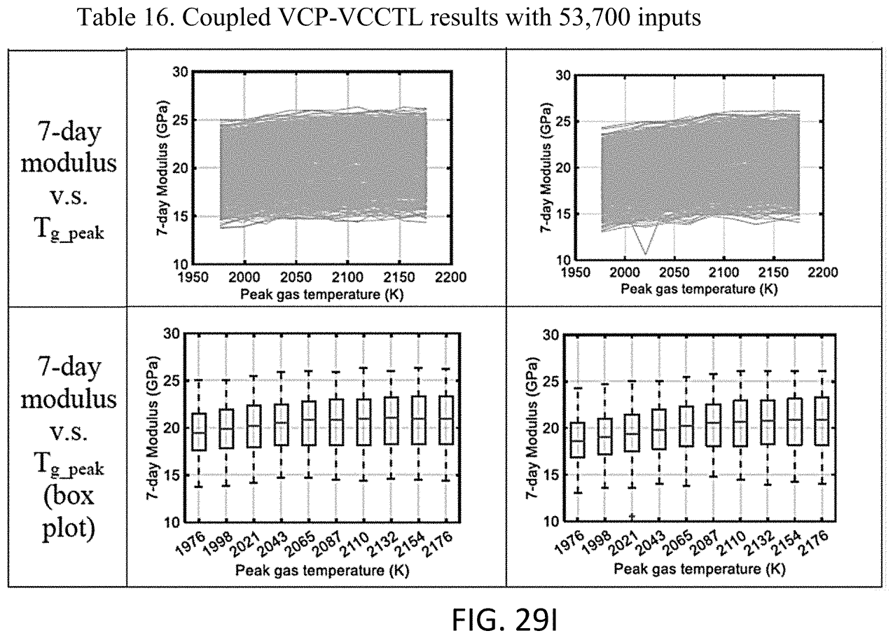

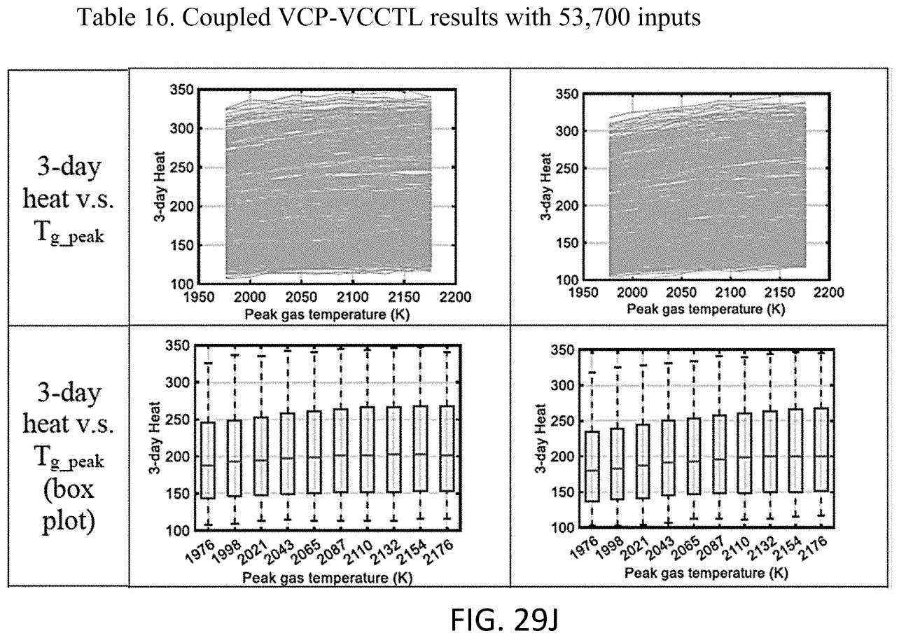

Table 16 (FIGS. 29A-29J) shows the results of coupled VCP-VCCTL with 53,700 inputs. Based on the output of VCP, mass fractions of different cement clinker phases are plotted versus different peak gas temperature and peak gas locations (also known as flame locations). For example, the first plot in Table 16 (FIGS. 29A-29J) shows alite mass fraction of virtual cements with 537 raw meal combinations versus 10 peak gas temperatures. The results indicate that alite increases with the peak gas temperature (or the highest temperature of flame inside the kiln), belite decreases with the peak gas temperature, and CaO decreases with the peak gas temperature. The sensitivity of clinker phases to temperature is increased when the flame is close to the exit of the kiln. That means, if more alite is desired, one could move the flame position closer to the kiln exit, which provides more of an influence than just increase the peak gas temperature. Similarly, based on the output of coupled VCP-VCCTL model, 7-day modulus and 3-day heat of hydration has a similar trend with peak gas temperature and flame position. This case gives meaningful guidance for the design of a cement kiln. Instead of increasing the maximum temperature of the flame inside the kiln to create a cement with higher early strength, a simple position change of the flame is more energy efficient and sustainable.

### Optimization of VCP-VCCTL Model

This section describes an optimization tool for cement by applying PSO on a coupled VCP-VCCTL model to save material cost, energy consumption, and decrease CO₂ emission.

Cost vs. Modulus

The production of cement typically involves two major costs: energy and materials. The cost of energy is reported to represent a total of 20-40% of the total cost.

First, the cost of raw material for the cement plant was estimated and is provided in Table 17, which lists the unit price for cement raw material in current market (sand and gravel only).

TABLE 17
Unit price for raw material of cement plant

| Raw material | Chemical Composition | Unit Price($/Ton) |
|---|---|---|
| Limestone | CaCO₃ + CaO | 30 |
| Sand and Gravel | SiO₂ | 8.8 |
| Clay | Al₂O₃ + Fe₂O₃ | 8 |

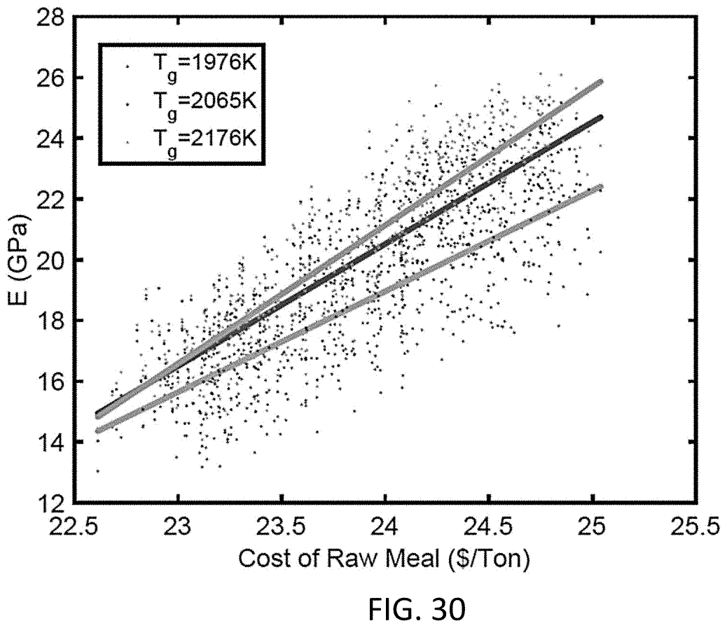

By incorporating the unit price into the VCP model discussed in the previous section based on the mass fraction of raw meal, the relationship between 7-day modulus and raw meal cost was calculated, which is shown in FIG. 30. Modulus is observed to increase with the cost of raw meal, which is due to the increase of limestone used as raw meal. From the linear regression fit for the data, a positive correlation between gas peak temperature and modulus is obtained, which matches with the results from Table 15 (FIGS. 27A-27D).

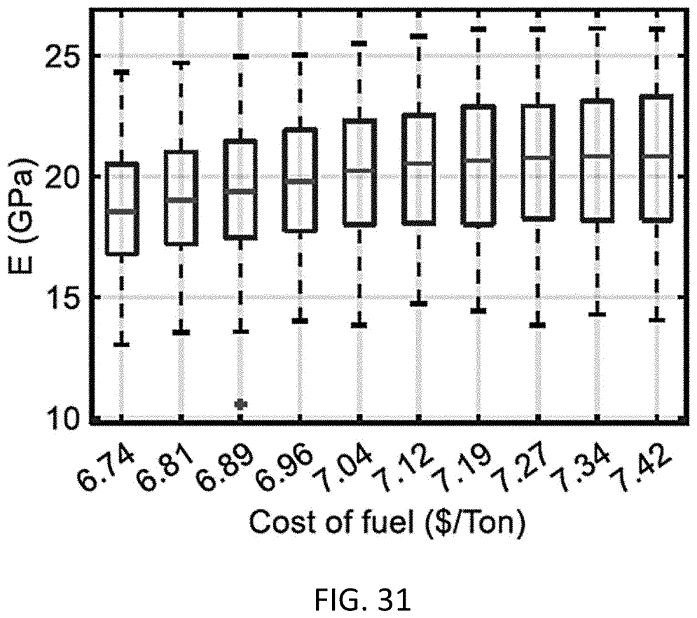

After the material cost is calculated, energy cost, or cost of fuel is considered. The average energy to produce one ton of cement can be estimated as 3.3 GJ, which can be generated by 120 kg coal with a calorific value of 27.5 MJ/kg. Coal is the major fuel used for cement production. The cost of coal is $2.07/GJ. FIG. 31 shows the relationship between modulus and cost of fuel. Because of the linear relation between energy and temperature, the cost of fuel has a linear relationship with temperature.

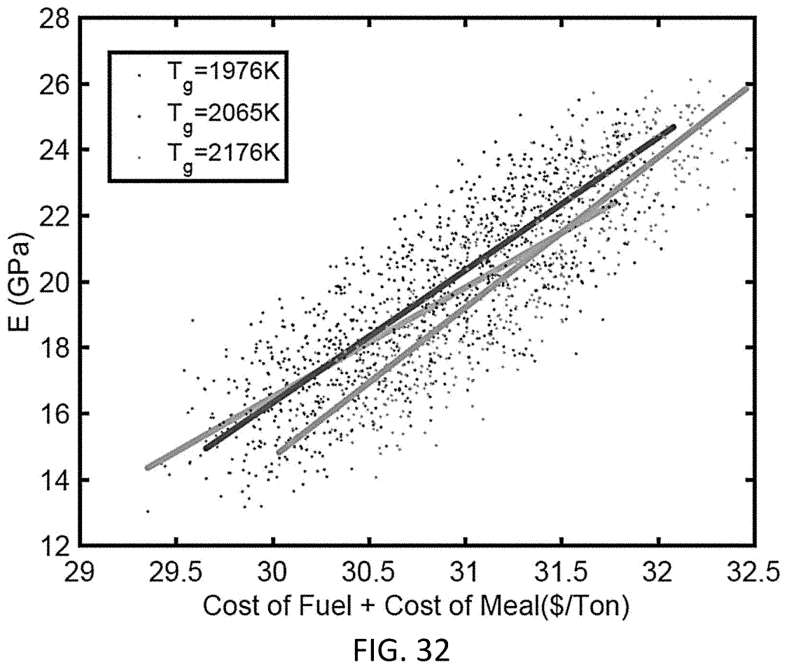

FIG. 32 shows the relationship between modulus and total cost by combining material cost and fuel cost. Similar to FIG. 30, modulus increases with total cost while the relationship between the modulus and temperature is not as clear as in FIG. 30 due to the effect of fuel cost. From FIG. 32, it can be seen that energy cost accounts for about 30% of the total cost.

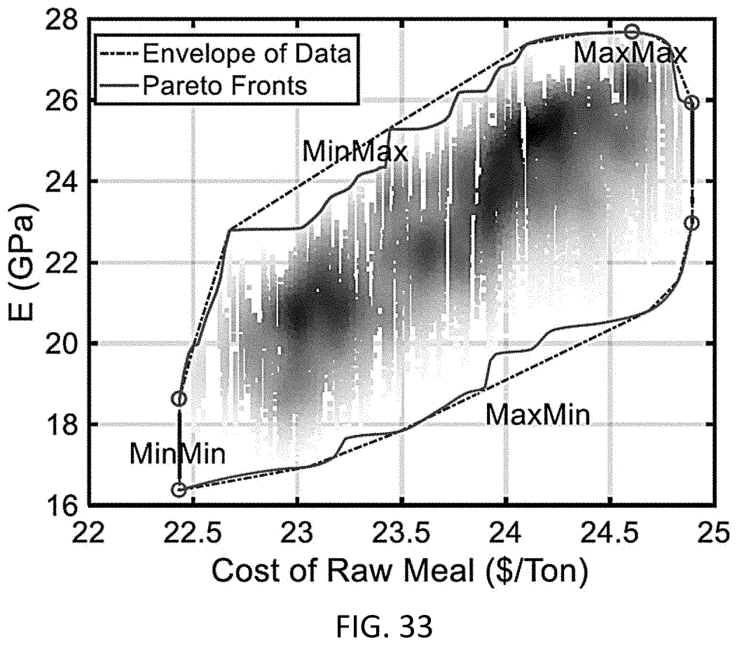

The multi-objective PSO tool was integrated into the coupled VCP-VCCTL model to create an integrated computational optimization VCP-VCCTL tool for energy saving, cost saving and greenhouse gas emissions reduction without sacrificing cement productivity and performance. Pareto fronts of four different bi-objective scenarios are plotted in FIG. 33 to show the clear trade-off between modulus and material cost. In FIG. 33, the Min (cost of raw meal)−Max(E) Pareto front is what the cement industry wants. To preserve strength, the cost cannot be reduced too much from 24.7 to 24.1 $/Ton (2.43% savings). From the Min-Max Pareto front, it can be seen that some modulus have to be sacrificed if less cost is needed. Most of the cement used for FIG. 33 is cheaper and weaker.

CO2 Emission vs. Modulus

As indicated above, 50% of the total emission comes from calcination/decomposition of limestone inside the cement kiln, which is a considerable amount of emission. Reduction of CO₂ emission from limestone is taken into consideration in this section.

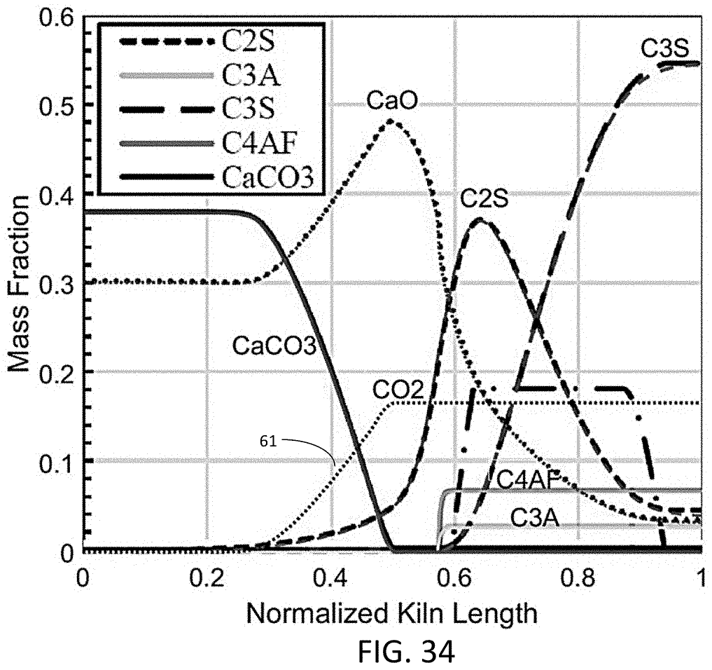

The VCP kiln model described above calculated the mass fraction of CO₂ from limestone decomposition using Equation 16. The mass fraction of CO₂ emission from limestone decomposition is represented in FIG. 34 by dashed line 61.

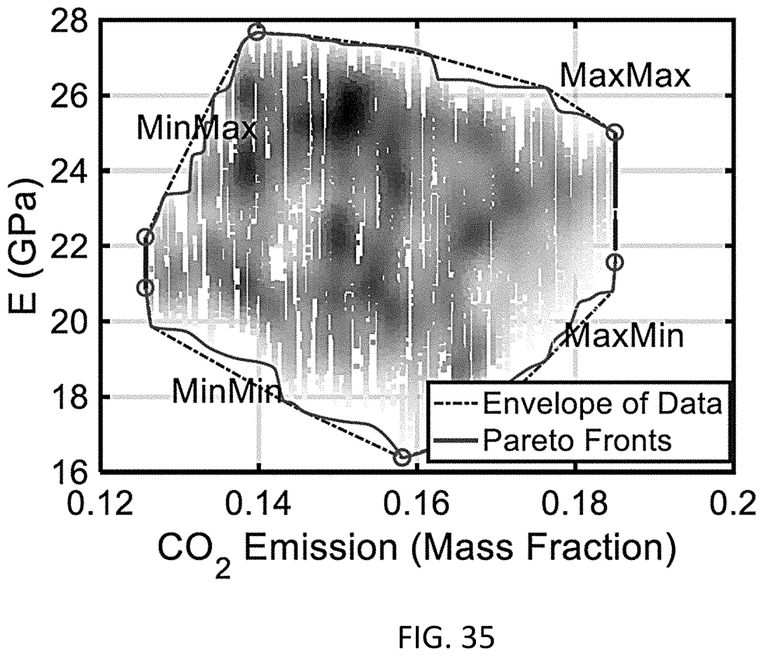

In order to reduce CO₂ emissions without sacrificing cement strength, CO₂ emission from limestone and 7-day modulus are considered as the objectives in PSO at the same time. FIG. 35 shows the four Pareto fronts for different optimization scenarios on E vs. CO₂ emission from limestone decomposition. In FIG. 35, the Min(CO₂ emission)−Max(E) Pareto front is what the cement industry wants. The point with 0.14 CO₂ emission and 27.8 GPa is the optimal cement. Most of the cement gives more emissions without sacrificing too much strength. More alite means more decomposition, which typically gives more strength. The results of this optimization indicate that the coupled VCP/VCCTL model can be used as a tool to optimize the design of the cement.

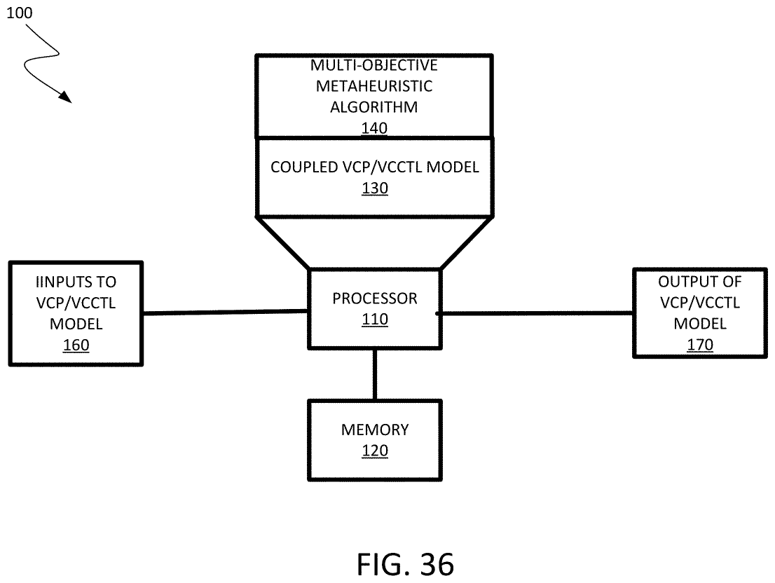

FIG. 36 is a block diagram of the system 100 in accordance with a representative embodiment for executing the coupled VCP/VCCTL model 130 and the multi-objective metaheuristic algorithm 140. As indicated above, the VCP/VCCTL model and the multi-objective metaheuristic algorithm are typically executed by a high performance computing cluster, which is represented in FIG. 36 by the processor 110, which can be one or more processors, and memory 120, which can be one or more memory devices. The processor 110 of the system 100 is configured to perform the coupled VCP/VCCTL model 130 and the multi-objective metaheuristic algorithm 140 to perform the process described above with reference to the representative embodiment shown in FIG. 28. Blocks 160 and 170 represent the input to and output generated by the processor 110. The output 170 can be in any suitable format, such as one or more printed or displayed Pareto fronts described above, for example.

The model 130 and the algorithm 140 can be implemented in hardware, software, firmware, or a combination thereof, but they are typically implemented in software. Any or all portions of the model 130 and algorithm 140 that are implemented in software and/or firmware being executed by a processor (e.g., processor 110) can be stored in a non-transitory memory device, such as the memory 120. For any component discussed herein that is implemented in the form of software, any number of programming languages may be employed such as, for example, C, C++, C#, Objective C, Java®, JavaScript®, Perl, PHP, Visual Basic®, Python®, Ruby, Flash®, or other programming languages. The term “executable” means a program file that is in a form that can ultimately be run by the processor 110. Examples of executable programs may be, for example, a compiled program that can be translated into machine code in a format that can be loaded into a random access portion of the memory 120 and run by the processor 110, source code that may be expressed in proper format such as object code that is capable of being loaded into a random access portion of the memory 120 and executed by the processor 110, or source code that may be interpreted by another executable program to generate instructions in a random access portion of the memory 110 to be executed by the processor 110, etc. An executable program may be stored in any portion or component of the memory 120 including, for example, random access memory (RAM), read-only memory (ROM), hard drive, solid-state drive, USB flash drive, memory card, optical disc such as compact disc (CD) or digital versatile disc (DVD), floppy disk, magnetic tape, static random access memory (SRAM), dynamic random access memory (DRAM), magnetic random access memory (MRAM), a programmable read-only memory (PROM), an erasable programmable read-only memory (EPROM), an electrically erasable programmable read-only memory (EEPROM), or other like memory device.

### CONCLUSIONS

In summary, the present disclosure discloses the metaheuristic algorithms applied to virtual cement and cement plant modeling. Single-objective and multi-objective optimizations with PSO and GA are applied to a set of sample cement data from VCCTL. A scoring system is created to evaluate cement based on Pareto front optimization results. A 1-D physical-chemical cement rotary kiln model is simulated with Matlab2016a solver and integrated with VCCTL and a multi-objective metaheuristic algorithm on a high performance computing cluster. A computational framework simulating cement and cement plant intelligently based on user's specifications and guiding the optimal designs is disclosed.

The integrated, or coupled, model can provide a quantitative optimization tool for different energy efficiency measures addressed from cement plants and reduce energy, material consumption and greenhouse gas emissions without losing the performance of material.

It should be noted that the inventive principles and concepts have been described herein with reference to a few representative embodiments, experiments and computer simulations. It will be understood by those skilled in the art in view of the description provided herein that the inventive principles and concepts are not limited to these embodiments or examples. Many modifications may be made to the systems and methods described herein within the scope of the disclosure, as will be understood by those of skill in the art.

What is claimed is:

1. A system for modeling cement and a cement kiln plant, the system comprising:
at least a first processor configured to perform an integrated modeling computer program comprising a Virtual Cement and Concrete Testing Laboratory (VCCTL) modeling computer program and a virtual cement plant (VCP) modeling computer program, the VCP modeling computer program receiving VCP input and producing a VCP output, the VCCTL modeling computer program receiving the VCP output and producing a virtual cement performance based at least in part on the VCP output received by the VCCTL modeling computer program from the VCP modeling computer program; and
memory in communication with said at least a first processor.

2. The system of claim 1, wherein said at least a first processor is also configured to perform one or more multi-objective metaheuristic optimization computer programs.

3. The system of claim 2, wherein said one or more multi-objective metaheuristic optimization computer programs terminate when preselected convergence criteria are met.

4. The system of claim 2, wherein said one or more multi-objective metaheuristic optimization computer programs generate a plurality of Pareto fronts from the output of the integrated modeling computer program.

5. The system of claim 4, wherein a respective Pareto front is generated for each of a plurality of objectives of a multi-objective optimization problem associated with the VCCTL modeling computer program.

6. The system of claim 2, wherein said one or more multi-objective metaheuristic optimization computer programs perform at least one of a particle swarm optimization (PSO) algorithm and a genetic algorithm (GA).

7. The system of claim 2, wherein the virtual cement performance provides information regarding control parameters for the cement kiln plant that can be adjusted to reduce material costs and consumption.

8. The system of claim 7, wherein the virtual cement performance provides information regarding control parameters for the cement kiln plant that can be adjusted to decrease carbon dioxide emissions that are emitted by the cement kiln plant.

9. A method for modeling cement and a cement kiln plant, the method comprising:
in at least a first processor:
performing an integrated modeling computer program comprising a Virtual Cement and Concrete Testing Laboratory (VCCTL) modeling computer program and a virtual cement plant (VCP) modeling computer program, the VCP modeling computer program receiving VCP input and producing a VCP output; and
receiving the VCP output in the VCCTL modeling computer program and performing the VCCTL modeling computer program to produce a virtual cement performance based at least in part on the VCP output received by the VCCTL modeling computer program from the VCP modeling computer program.

10. The method of claim 9, further comprising:
in at least the first processor:
performing one or more multi-objective metaheuristic optimization computer programs.

11. The method of claim 10, wherein said one or more multi-objective metaheuristic optimization computer programs terminate when preselected convergence criteria are met.

12. The method of claim 10, wherein said one or more multi-objective metaheuristic optimization computer programs generate a plurality of Pareto fronts from the output of the integrated modeling computer program.

13. The method of claim 12, wherein a respective Pareto front is generated for each of a plurality of objectives of a multi-objective optimization problem associated with the VCCTL modeling computer program.

14. The method of claim 10, wherein said one or more multi-objective metaheuristic optimization computer programs comprise at least one of a particle swarm optimization (PSO) algorithm and a genetic algorithm (GA).

15. The method of claim 14, wherein the virtual cement performance provides information regarding control parameters for the cement kiln plant that can be adjusted to decrease carbon dioxide emissions that are emitted by the cement kiln plant.

16. The method of claim 10, wherein the virtual cement performance provides information regarding control parameters for the cement kiln plant that can be adjusted to reduce material costs and consumption.

17. An integrated modeling computer program comprising a Virtual Cement and Concrete Testing Laboratory (VCCTL) modeling computer program and a virtual cement plant (VCP) modeling computer program, the integrated modeling computer program comprising computer instructions for execution by at least a first processor, the integrated modeling computer program comprising:
VCP modeling computer instructions that receive VCP input and produce VCP output; and
VCCTL modeling computer instructions that receive the VCP output and produce a virtual cement performance based at least in part on the VCP output received by the VCCTL modeling computer program from the VCP modeling computer program.

18. The integrated modeling computer program of claim 17, further comprising:
multi-objective metaheuristic optimization computer instructions.

19. The integrated modeling computer program of claim 18, wherein the multi-objective metaheuristic optimization computer instructions comprise instructions for generating a plurality of Pareto fronts.

20. The integrated modeling computer program of claim 17, wherein the multi-objective metaheuristic optimization computer instructions comprise instructions for performing at least one of a particle swarm optimization (PSO) algorithm and a genetic algorithm (GA).
